(19) United States
(12) Patent Application Publication
(10) Pub. No.: US 2026/0239834 A1
(43) Pub. Date: Aug. 13, 2026

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., Ltd., Yongin-si (KR)

(72) Inventors: Kwangwoo PARK, Yongin-si (KR); Veidhes BASRUR, Yongin-si (KR); Yeonha BAEK, Yongin-si (KR); Hyunjun YOO, Yongin-si (KR)

(73) Assignee: Samsung Display Co., Ltd., Yongin-si (KR)

(21) Appl. No.: 19/336,974

(22) Filed: Sep. 23, 2025

(30) Foreign Application Priority Data
Feb. 10, 2025 (KR) 10-2025-0016701

(51) Int. Cl. H10K 59/131; H10K 59/12; H10K 59/124; H10K 59/80

(52) U.S. Cl. CPC H10K 59/131; H10K 59/1201; H10K 59/124; H10K 59/873

(57) ABSTRACT

A display device may include a substrate including a first area, a second area surrounding the first area, and a display area surrounding the second area; pixels on the display area; a data bypass line on the second area; a first insulating layer on the data bypass line; a scan bypass line on the first insulating layer over the second area; a second insulating layer on the first insulating layer and including a concave portion and a convex portion which define an uneven structure, wherein the convex portion may overlap the scan bypass line in a plan view; and a common electrode along a profile of the uneven structure. The first and second insulating layers may define part of a through hole over the first area. The data bypass line and the scan bypass line may extend to bend along a border of the through hole in the plan view.

### CROSS-REFERENCE TO RELATED APPLICATION

This application claims priority under 35 USC § 119 to Korean Patent Application No. 10-2025-0016701, filed on Feb. 10, 2025 in the Korean Intellectual Property Office, the content of which is herein incorporated by reference in its entirety.

### BACKGROUND

### 1. Field

The present disclosure relates generally to a display device. More particularly, the present disclosure relates to a display device, a method of manufacturing the display device, and/or an electronic device including the display device.

### 2. Description of the Related Art

With the development of information technology, the importance of a display device, which may be a connection medium between a user and information, has been highlighted. For example, the use of display devices such as liquid crystal display (LCD) device, organic light emitting diode (OLED) display device, plasma display panel (PDP) device, quantum dot display device or the like is increasing.

In order for a user to perform various functions by using the display device, a functional module (e.g., a camera module or the like) may be arranged in the display device. In order for the functional module to function efficiently, it may be necessary to increase the transmittance of light incident to the functional module. In addition, in order to enlarge a display area of the display device, a structure in which the functional module is arranged to overlap the display area has been developed.

### SUMMARY

Embodiments provide a display device with improved display quality.

Embodiments provide a method of manufacturing the display device.

Embodiments provide an electronic device including the display device.

A display device according to an embodiment of the present disclosure may include a substrate comprising a first area, a second area surrounding the first area in a plan view, and a display area surrounding the second area in the plan view; pixels on the display area of the substrate; a data bypass line on the second area of the substrate; a first insulating layer on the data bypass line; a scan bypass line on the first insulating layer on the second area of the substrate; a second insulating layer on the first insulating layer, the second insulating layer covering the scan bypass line, the second insulating layer including a concave portion and a convex portion which define an uneven structure, wherein the convex portion may overlap the scan bypass line in the plan view; and a common electrode on the second insulating layer and disposed along a profile of the uneven structure. The first insulating layer and the second insulating layer may define part of a through hole over the first area of the substrate. The data bypass line may extend to bend along a border of the through hole in the plan view, and the scan bypass line may extend to bend along the border of the through hole in the plan view.

In some embodiments, the display device may further include a dam portion on the second insulating layer and overlapping the uneven structure. The common electrode may be disposed along the profile of the uneven structure and a profile of the dam portion.

In some embodiments, the dam portion may overlap the convex portion of the uneven structure.

In some embodiments, the dam portion may overlap the concave portion of the uneven structure.

In some embodiments, the dam portion may be spaced apart from the scan bypass line in the plan view.

In some embodiments, the scan bypass line may include a plurality of scan bypass lines, and the plurality of scan bypass lines may include a first scan bypass line and a second scan bypass line. The first scan bypass line may overlap the dam portion in the plan view, and the second scan bypass line may overlap the convex portion of the uneven structure in the plan view.

In some embodiments, the display device may further include a gate electrode on the display area on the substrate, a capacitor electrode on the gate electrode, a source electrode and a drain electrode on the capacitor electrode, and a connection electrode on the drain electrode. The data bypass line may include a plurality of data bypass lines, and the plurality of data bypass lines may include a first data bypass line and a second data bypass line. The first data bypass line and the second data bypass line may be disposed in different layers.

In some embodiments, the first data bypass line may be in a same layer as the gate electrode. The second data bypass line may be in a same layer as the capacitor electrode. The scan bypass line may be in a same layer as the connection electrode.

In some embodiments, the display device may further include a first driver in a peripheral area of the substrate; and a second driver in the peripheral area of the substrate. The peripheral area of the substrate may further surround at least a portion of the display area. The first driver may be adjacent to a first side of the display area. The second driver may be adjacent to a second side of the display area. The second side of the display area may be opposite the first side of the display area. The first driver may be configured to output a scan signal to the scan bypass line while the scan signal is not output by the second driver.

In some embodiments, the display device may further include a constant voltage line between the data bypass line and the scan bypass line, and the constant voltage line may be configured to have a constant voltage applied thereto. The scan bypass line may overlap the constant voltage line in the plan view.

In some embodiments, the display device may further include a plurality of constant voltage patterns spaced apart from each other between the data bypass line and the scan bypass line. The plurality of constant voltage patterns may be configured to have a constant voltage applied thereto. The scan bypass line may include a plurality of scan bypass lines, and the plurality of scan bypass lines may overlap the plurality of constant voltage patterns in the plan view, respectively.

In some embodiments, the first insulating layer may define a plurality of via-holes between the plurality of constant voltage patterns.

In some embodiments, the second insulating layer may be disposed along a profile of the first insulating layer.

In some embodiments, the plurality of scan bypass lines may be between the plurality of via-holes in the plan view.

A method of manufacturing a display device according to an embodiment of the present disclosure may include forming a data bypass line on a second area of a substrate, the substrate including a first area, the second area surrounding the first area in a plan view, and a display area surrounding the second area in the plan view; forming a first insulating layer on the data bypass line; forming a scan bypass line on the first insulating layer over the second area of the substrate; forming a second insulating layer on the first insulating layer and covering the scan bypass line, the second insulating layer including a concave portion and a convex portion which may define an uneven structure on the first insulating layer; and forming a common electrode disposed along a profile of the uneven structure on the second insulating layer. The concave portion may overlap the scan bypass line in the plan view.

In some embodiments, the forming the second insulating layer may include forming a preliminary insulating layer covering the scan bypass line on the first insulating layer and patterning the preliminary insulating layer using a photomask comprising a semi-transmitting portion.

In some embodiments, the forming the scan bypass line may include forming a plurality of scan bypass lines on the first insulating layer over the second area of the substrate. The photomask may include a light-blocking portion which may overlap the plurality of scan bypass lines in the plan view and the semi-transmitting portion which may overlap spaced areas between the plurality of scan bypass lines in the plan view.

In some embodiments, the method may further include forming a constant voltage line over the data bypass line before forming the scan bypass line. The constant voltage line may be between the data bypass line and the scan bypass line. The constant voltage line may be configured to have a constant voltage applied thereto.

In some embodiments, the forming the first insulating layer may include forming a preliminary insulating layer covering the constant voltage line on the data bypass line and forming the first insulating layer in which a plurality of via-holes are defined and a plurality of constant voltage patterns spaced apart from each other by patterning the preliminary insulating layer and the constant voltage line, respectively. The second insulating layer may be disposed along a profile of the first insulating layer.

An electronic device according to an embodiment of the present disclosure may include a display device; and a processor configured to transmit an image data signal and an input control signal to the display device. The display device may include a substrate comprising a first area, a second area surrounding the first area in a plan view, and a display area surrounding the second area in the plan view; pixels on the display area of the substrate; a functional module under the substrate and overlapping the first area; a data bypass line on the second area of the substrate; a first insulating layer on the data bypass line; a scan bypass line on the first insulating layer on the second area of the substrate; a second insulating layer on the first insulating layer, the second insulating layer covering the scan bypass line, and the second insulating layer including a concave portion and a convex portion which may define an uneven structure, wherein the convex portion may overlap the scan bypass line in the plan view; and a common electrode on the second insulating layer and along a profile of the uneven structure. The first insulating layer and the second insulating layer may define part of a through hole over the first area of the substrate. The data bypass line may extend to bend along a border of the through hole in the plan view. The scan bypass line may extend to bend along the border of the through hole in the plan view.

A display device according to embodiments of the present disclosure may include a substrate including a first area in which a through hole is defined, a second area surrounding the first area in a plan view and a display area surrounding the second area in a plan view and in which pixels are disposed, a first via-insulating layer disposed on the substrate, a scan bypass line disposed in the second area on the first via-insulating layer and extending to bend along a border of the through hole in a plan view, a second via-insulating layer disposed on the first via-insulating layer, covering the scan bypass line, and including a concave portion and a convex portion that define an uneven structure, and a common electrode disposed on the second via-insulating layer and disposed along a profile of the uneven structure. The convex portion may overlap the scan bypass line in a plan view.

As the common electrode is disposed along the profile of the convex portion of the uneven structure, the convex portion may increase a separation distance between the scan bypass line and the common electrode. Accordingly, the scan bypass line may not be electrically connected to the common electrode. That is, a lighting defect caused by the scan bypass line being electrically shorted with the common electrode may be limited and/or prevented. As a result, the display quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a plan view illustrating the display device of FIG. 1.

FIG. 3A is a circuit diagram illustrating an example of a circuit structure of pixel included in the display device of FIG. 1.

FIG. 3B is a circuit diagram illustrating another example of a circuit structure of a pixel included in the display device of FIG. 1.

FIG. 4 is a cross-sectional view taken along the line I-I′ of FIG. 2.

FIG. 5 is a diagram illustrating an example of signals applied to a pixel included in the display device of FIG. 1.

FIG. 6 is an enlarged plan view illustrating the area A of FIG. 2.

FIG. 7 is a cross-sectional view taken along the line II-II′ of FIG. 6.

FIG. 8 is a cross-sectional view illustrating a display device according to an embodiment of the present disclosure.

FIG. 9 is a cross-sectional view illustrating a display device according to an embodiment of the present disclosure.

FIG. 10 is a plan view illustrating a display device according to an embodiment of the present disclosure.

FIG. 11 is a cross-sectional view taken along the line III-III′ of FIG. 10.

FIG. 12 is a cross-sectional view illustrating a display device according to an embodiment of the present disclosure.

FIG. 13 is a cross-sectional view illustrating a display device according to an embodiment of the present disclosure.

FIGS. 14, 15, 16, 17, 18, and 19 are cross-sectional views illustrating a method of manufacturing a display device according to an embodiment of the present disclosure.

FIGS. 20, 21, 22, 23, and 24 are cross-sectional views illustrating a method of manufacturing a display device according to an embodiment of the present disclosure.

FIG. 25 is a block diagram of an electronic device according to an embodiment of the present disclosure.

FIG. 26 is a schematic view of an electronic device according to various embodiments.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

The notion that elements are “substantially the same” may indicate that the element may be completely the same and may also indicate that the elements may be determined to be the same in consideration of errors or deviations occurring during a process.

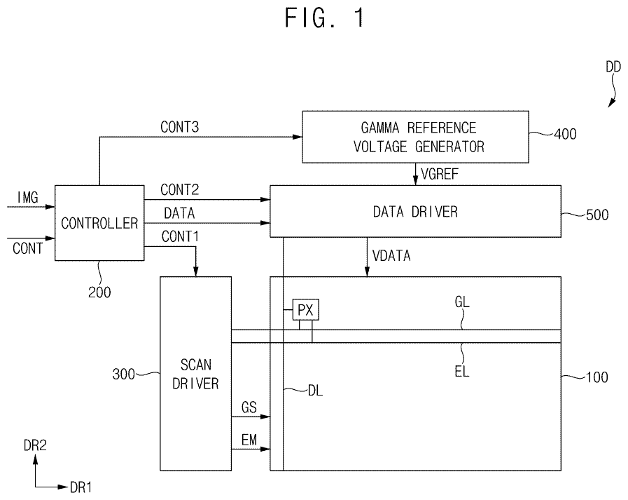

FIG. 1 is a block diagram illustrating a display device according to an embodiment of the present disclosure.

Referring to FIG. 1, a display device DD according to an embodiment of the present disclosure may include a display panel 100 and a panel driver that drives the display panel 100. The panel driver may include a controller 200, a scan driver 300, a gamma reference voltage generator 400, and a data driver 500.

For example, the controller 200 and the data driver 500 may be integrally formed. A driving module in which the controller 200 and the data driver 500 are integrally formed may be referred to as a timing controller embedded data driver (TED).

The display panel 100 may include gate lines GL, emission lines EL, data lines DL, and pixels PX. The pixels PX may be electrically connected to the gate lines GL, the emission lines EL, and the data lines DL. Each of the pixels PX may generate light in response to a driving signal. For example, each of the gate lines GL may extend in a first direction DR1, and each of the emission lines EL may extend in the first direction DR1. Each of the data lines DL may extend in a second direction DR2 intersecting the first direction DR1. For example, the first direction DR1 and the second direction DR2 may be perpendicular to each other.

The controller 200 may receive an input image data signal IMG and an input control signal CONT from an external device. For example, the input image data signal IMG may include red image data, green image data, and blue image data, but is not limited thereto. The input image data signal IMG may further include white image data. The input control signal CONT may include a vertical synchronization signal, a horizontal synchronization signal, a data enable signal, a master clock signal, or the like.

The controller 200 may generate a first control signal CONT1, a second control signal CONT2, a third control signal CONT3, and a data signal DATA based on the input image data signal IMG and the input control signal CONT. The controller 200 may output the first control signal CONT1 to the scan driver 300. The first control signal CONT1 may include a vertical start signal and a clock signal. The controller 200 may output the second control signal CONT2 and the data signal DATA to the data driver 500. The second control signal CONT2 may include a horizontal start signal and a load signal. The controller 200 may output the third control signal CONT3 to the gamma reference voltage generator 400.

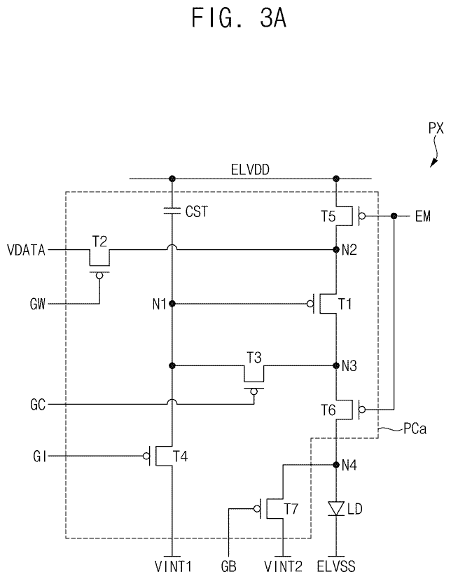

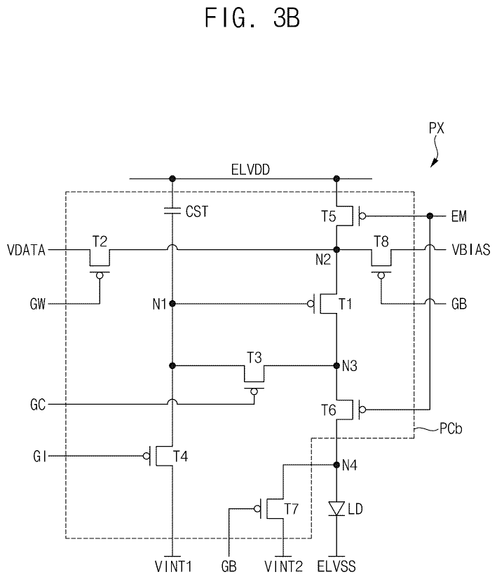

The scan driver 300 may generate gate signals GS and emission signals EM in response to the first control signal CONT1. The scan driver 300 may output the gate signals GS to the gate lines GL. In addition, the scan driver 300 may output the emission signals EM to the emission lines EL. In an embodiment, the gate signals GS may include a write gate signal GW, a compensation gate signal GC, an initialization gate signal GI, and a bias gate signal GB illustrated in FIGS. 3A and 3B. However, the present disclosure is not necessarily limited thereto.

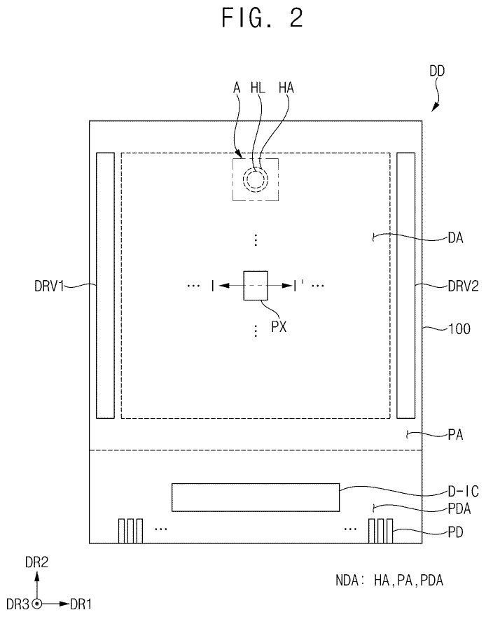

The scan driver 300 may be disposed in a peripheral area (PA, see FIG. 2) on the display panel 100. For example, the scan driver 300 may be mounted in the peripheral area on the display panel 100. The scan driver 300 may correspond to a first driver DRV1 and a second driver DRV2 of FIG. 2.

The gamma reference voltage generator 400 may generate a gamma reference voltage VGREF in response to the third control signal CONT3. The gamma reference voltage generator 400 may provide the gamma reference voltage VGREF to the data driver 500. For example, the gamma reference voltage generator 400 may be disposed in the controller 200, or in the data driver 500.

The data driver 500 may receive the second control signal CONT2 and the data signal DATA from the controller 200, and may receive the gamma reference voltage VGREF from the gamma reference voltage generator 400. The data driver 500 may convert the data signal DATA into an analog form of a data voltage VDATA using the gamma reference voltage VGREF. The data driver 500 may output the data voltage VDATA to the data lines DL.

In an embodiment, the data driver 500 may be disposed in a pad area (PDA, see FIG. 2) on the display panel 100. For example, the data driver 500 may be mounted in the pad area on the display panel 100. The data driver 500 may correspond to a driving chip D-IC of FIG. 2.

FIG. 2 is a plan view illustrating the display device of FIG. 1.

In this specification, a plane may be defined by the first direction DR1 and the second direction DR2, and a direction normal to the plane may be a third direction DR3. In other words, the third direction DR3 may be perpendicular to each of the first direction DR1 and the second direction DR2. As used herein the “plan view” is a view in the third direction DR3.

Referring to FIG. 2, the display device DD may include the display panel 100, a driving chip D-IC, a first driver DRV1, and a second driver DRV2.

The display panel 100 may include a display area DA and a non-display area NDA. The display area DA may be defined as an area that displays an image by generating light or adjusting the transmittance of light provided from an external light source. The display panel 100 may include the pixels PX disposed in the display area DA. Each of the pixels PX may generate light in response to a driving signal. For example, the pixels PX may be disposed in a matrix form along the first direction DR1 and the second direction DR2.

The non-display area NDA may be defined as an area where an image is not displayed. The non-display area NDA may include a hole area HA, a peripheral area PA, and a pad area PDA.

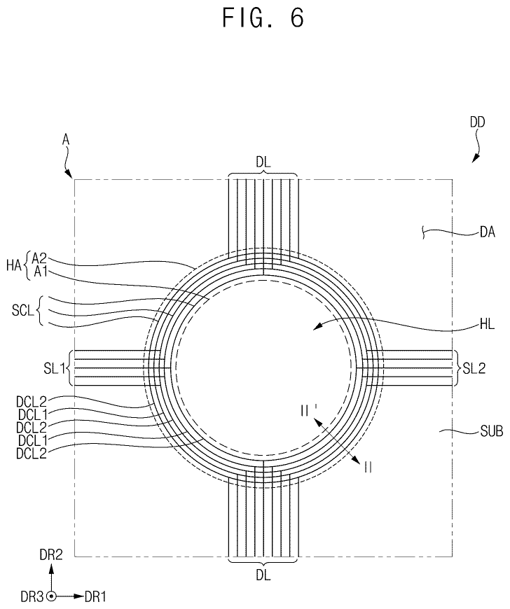

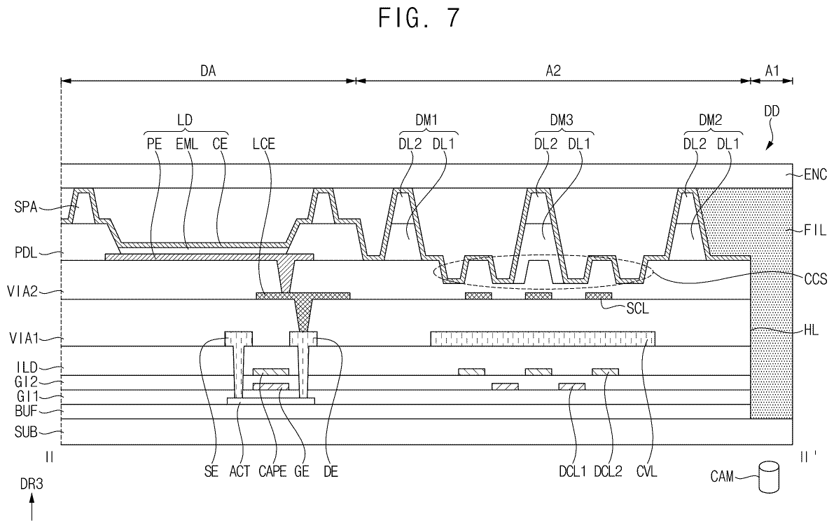

The hole area HA may have a higher transmittance than the display area DA. Natural light, visible light, infrared light, or the like may travel into an interior of the display device DD through the hole area HA. The display device DD may further include a functional module (CAM, see FIG. 7) that captures an external image using visible light passing through the hole area HA or determines the accessibility of an external object using infrared light. The functional module may overlap the hole area HA in a plan view. The hole area HA may be surrounded by the display area DA. A through hole HL surrounded by the pixels PX in a plan view may be defined in the hole area HA. A detailed description thereof will be described below with reference to FIGS. 6 and 7.

Although FIG. 2 illustrates a case where the through hole HL is disposed on an upper side of the display device DD, the present disclosure is not necessarily limited thereto. The specific location of the through hole HL may be changed according to embodiments. In addition, although FIG. 2 illustrates a case where the through hole HL has a circular planar shape, the present disclosure is not necessarily limited thereto. The shape of the through hole HL may have various planar shapes, such as a polygon (e.g., a square), an oval, or the like.

The peripheral area PA may be adjacent to the display area DA. The peripheral area PA may surround at least a portion of the display area DA in a plan view. For example, the peripheral area PA may entirely surround the display area DA in a plan view.

The first driver DRV1 and the second driver DRV2 may be disposed in the peripheral area PA on the display panel 100. The first driver DRV1 and the second driver DRV2 may be spaced apart from each other. The first driver DRV1 may be disposed in the peripheral area PA adjacent to a first side of the display area DA, and the second driver DRV2 may be disposed in the peripheral area PA adjacent to a second side opposite to the first side of the display area DA. For example, the first driver DRV1 may be disposed in the peripheral area PA adjacent to a left side of the display area DA, and the second driver DRV2 may be disposed in the peripheral area PA adjacent to a right side of the display area DA. For example, each of the first driver DRV1 and the second driver DRV2 may correspond to the scan driver 300 of FIG. 1. In an embodiment, any one of the first driver DRV1 and the second driver DRV2 may be omitted.

The pad area PDA may be spaced apart from the display area DA. For example, the pad area PDA and the display area DA may be spaced apart from each other in the second direction DR2. For example, the pad area PDA may be spaced from the display area DA by the peripheral area PA in a plan view. The display panel 100 may further include pads PD disposed in the pad area PDA.

The driving chip D-IC may be disposed in the pad area PDA on the display panel 100. The driving chip D-IC may be connected to the pads PD through an anisotropic conductive film. The driving chip D-IC may provide the driving signal to the pixels PX. The driving signal may include various signals for driving the pixels PX, such as a driving voltage, a data voltage, or the like. The driving signal may be transmitted to the pixels PX through the driving chip D-IC and the pads PD. For example, the driving chip D-IC may correspond to the data driver 500 of FIG. 1.

Although not illustrated in FIG. 2, a printed circuit board may be disposed in the pad area PDA on the display panel 100. The printed circuit board may be connected to the pads PD through an anisotropic conductive film. For example, the printed circuit board may be a flexible printed circuit board (FPCB).

FIG. 3A is a circuit diagram illustrating an example of a circuit structure of a pixel included in the display device of FIG. 1.

Referring to FIG. 3A, each of the pixels PX may include a light-emitting element LD and a pixel driving circuit PCa connected to the light-emitting element LD. In an embodiment, the pixel driving circuit PCa may include first to seventh transistors T1, T2, T3, T4, T5, T6, and T7 and a storage capacitor CST. In FIG. 3A, the first to seventh transistors T1, T2, T3, T4, T5, T6, and T7 are illustrated as p-type transistors, but the present disclosure is not necessarily limited thereto. For example, the first transistor T1, the second transistor T2, the fifth transistor T5, the sixth transistor T6, and the seventh transistor T7 may be p-type transistors, and the third transistor T3 and the fourth transistor T4 may be n-type transistors.

The first transistor T1 may include a gate electrode, a first electrode, and a second electrode. The gate electrode of the first transistor T1 may be connected to a first node N1. The first electrode of the first transistor T1 may be connected to a second node N2. The first electrode of the first transistor T1 may receive a driving voltage ELVDD. The second electrode of the first transistor T1 may be connected to a third node N3. The first transistor T1 may provide a driving current to the light-emitting element LD.

The second transistor T2 may include a gate electrode, a first electrode, and a second electrode. The gate electrode of the second transistor T2 may receive a write gate signal GW. The first electrode of the second transistor T2 may receive the data voltage VDATA. The second electrode of the second transistor T2 may be connected to the second node N2.

The second transistor T2 may be turned on or off in response to the write gate signal GW. While the second transistor T2 is turned on, the second transistor T2 may provide the data voltage VDATA to the second node N2.

The third transistor T3 may include a gate electrode, a first electrode, and a second electrode. The gate electrode of the third transistor T3 may receive a compensation gate signal (GC). The first electrode of the third transistor T3 may be connected to the first node N1. The second electrode of the third transistor T3 may be connected to the third node N3.

The third transistor T3 may be turned on or off in response to the compensation gate signal GC. While the third transistor T3 is turned on, the third transistor T3 may diode-connect the first transistor T1. That is, the third transistor T3 may form a path for compensating the threshold voltage of the first transistor T1.

The fourth transistor T4 may include a gate electrode, a first electrode, and a second electrode. The gate electrode of the fourth transistor T4 may receive an initialization gate signal GI. The first electrode of the fourth transistor T4 may be connected to the first node N1. The second electrode of the fourth transistor T4 may receive a first initialization voltage VINT1.

The fourth transistor T4 may turn on or off in response to the initialization gate signal GI. While the fourth transistor T4 is turned on, the fourth transistor T4 may provide the first initialization voltage VINT1 to the first node N1. Accordingly, the fourth transistor T4 may provide the first initialization voltage VINT1 to the gate electrode of the first transistor T1 to initialize a voltage of the gate electrode of the first transistor T1.

The fifth transistor T5 may include a gate electrode, a first electrode, and a second electrode. The gate electrode of the fifth transistor T5 may receive an emission signal EM. The first electrode of the fifth transistor T5 may receive the driving voltage ELVDD. The second electrode of the fifth transistor T5 may be connected to the second node N2.

The fifth transistor T5 may turn on or off in response to the emission signal EM. While the fifth transistor T5 is turned on, the fifth transistor T5 may provide the driving voltage ELVDD to the second node N2.

The sixth transistor T6 may include a gate electrode, a first electrode, and a second electrode. The gate electrode of the sixth transistor T6 may receive the emission signal EM. The first electrode of the sixth transistor T6 may be connected to the third node N3. The second electrode of the sixth transistor T6 may be connected to a fourth node N4.

The sixth transistor T6 may be turned on or off in response to the emission signal EM. While the sixth transistor T6 is turned on, the sixth transistor T6 may electrically connect the second electrode of the first transistor T1 and an anode of the light-emitting element LD. Accordingly, the sixth transistor T6 may provide the driving current to the light-emitting element LD.

Although the fifth transistor T5 and the sixth transistor T6 are illustrated in FIG. 3A as being simultaneously driven by a substantially single emission signal EM, the present disclosure is not necessarily limited thereto. For example, the fifth transistor T5 and the sixth transistor T6 may be driven independently by different emission signals.

The seventh transistor T7 may include a gate electrode, a first electrode, and a second electrode. The gate electrode of the seventh transistor T7 may receive a bias gate signal GB. The first electrode of the seventh transistor T7 may be connected to the fourth node N4. The second electrode of the seventh transistor T7 may receive a second initialization voltage VINT2.

The seventh transistor T7 may be turned on or off in response to the bias gate signal GB. While the seventh transistor T7 is turned on, the seventh transistor T7 may provide the second initialization voltage VINT2 to the fourth node N4. Accordingly, the seventh transistor T7 may provide the second initialization voltage VINT2 to the anode of the light-emitting element LD to initialize a voltage of the anode.

The storage capacitor CST may include a first electrode and a second electrode. The first electrode of the storage capacitor CST may receive the driving voltage ELVDD. The second electrode of the storage capacitor CST may be connected to the first node N1.

The light-emitting element LD may include the anode and a cathode. The anode of the light-emitting element LD may be connected to the fourth node N4. The cathode of the light-emitting element LD may receive a common voltage ELVSS. The light-emitting element LD may generate light having a luminance corresponding to the driving current.

FIG. 3B is a circuit diagram illustrating another example of a circuit structure of a pixel included in the display device of FIG. 1.

Compared to the embodiment of the circuit structure of the pixel PX described above with reference to FIG. 3A, in an embodiment of the circuit structure of the pixel PX described with reference to FIG. 3B, a pixel driving circuit PCb may further include an eighth transistor T8. Accordingly, redundant descriptions of some components are omitted or summarized.

Referring to FIG. 3B, each of the pixels PX may include a light-emitting element LD and the pixel driving circuit PCb connected to the light-emitting element LD. In an embodiment, the pixel driving circuit PCb may include first to eighth transistors T1, T2, T3, T4, T5, T6, T7, and T8 and a storage capacitor CST. In FIG. 3B, the first to eighth transistors T1, T2, T3, T4, T5, T6, T7, and T8 are illustrated as p-type transistors, but the present disclosure is not necessarily limited thereto. For example, the first transistor T1, the second transistor T2, the fifth transistor T5, the sixth transistor T6, the seventh transistor T7, and the eighth transistor T8 may be p-type transistors, and the third transistor T3 and the fourth transistor T4 may be n-type transistors.

The eighth transistor T8 may include a gate electrode, a first electrode, and a second electrode. The gate electrode of the eighth transistor T8 may receive the bias gate signal GB. The first electrode of the eighth transistor T8 may receive a bias voltage VBIAS. The second electrode of the eighth transistor T8 may be connected to the second node N2.

The eighth transistor T8 may be turned on or off in response to the bias gate signal GB. While the eighth transistor T8 is turned on, the eighth transistor T8 may provide the bias voltage VBIAS to the first electrode of the first transistor T1.

In an embodiment, the seventh transistor T7 and the eighth transistor T8 may be simultaneously driven by the same bias gate signal GB, but the present disclosure is not necessarily limited thereto.

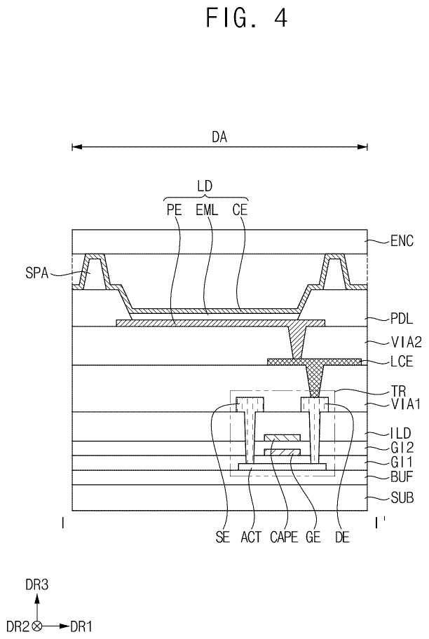

FIG. 4 is a cross-sectional view taken along the line I-I′ of FIG. 2.

Referring to FIG. 4, the display device DD may include a substrate SUB, a buffer layer BUF, a thin film transistor TR, a first gate insulating layer GI1, a second gate insulating layer GI2, a capacitor electrode CAPE, an inter-layer insulating layer ILD, a first via-insulating layer VIA1, a connection electrode LCE, a second via-insulating layer VIA2, the light-emitting element LD, a pixel defining layer PDL, a spacer SPA, and an encapsulation substrate ENC. The buffer layer BUF, first gate insulating layer GI1, second gate insulating layer GI2, inter-layer insulating layer ILD, first via-insulating layer VIA1, second via-insulating layer VIA2, pixel defining layer PDL, spacer SPA, and encapsulation substrate ENC may be stacked on top of each other on the substrate SUB.

The thin film transistor TR may include an active pattern ACT, a gate electrode GE, a source electrode SE, and a drain electrode DE. The light-emitting element LD may include a pixel electrode PE, a light-emitting layer EML, and a common electrode CE. The active pattern ACT may be formed on the buffer layer BUF and covered by the first gate insulating layer GI1. The gate electrode GE may be formed on the first gate insulating layer GI1 and covered by the second gate insulating layer GI2. The source electrode SE and drain electrode DE may be spaced apart from each other in the first direction DR1 and extend in the third direction DR3 through the interlayer insulating layer ILD, the second gate insulating layer GI2, and the first gate insulating layer GI1 to opposite ends of the active pattern ACT. The capacitor electrode CAPE may be on the second gate insulating layer GI2 and between the second gate insulating layer GI2 and the inter-layer insulating layer ILD.

The thin-film transistor TR of FIG. 4 may be a transistor that is connected to the light-emitting element LD through the connection electrode LCE. For example, the thin film transistor TR may be the sixth transistor T6 of FIGS. 3A and 3B.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, or the like. In an embodiment, the substrate SUB may include a quartz substrate (e.g., a synthetic quartz substrate, a fluorine-doped quartz substrate, or the like), a calcium fluoride substrate, a soda-lime glass substrate, a non-alkali glass substrate, or the like. These may be used alone or in combination with each other.

The buffer layer BUF may be disposed on the substrate SUB. The buffer layer BUF may limit and/or prevent diffusion of metal atoms, impurities, or the like from the substrate SUB to an upper structure. In addition, the buffer layer BUF may improve flatness of a surface of the substrate SUB when the surface of the substrate SUB is not uniform. The buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), or the like. These may be used alone or in combination with each other. In an embodiment, the buffer layer BUF may be omitted.

The active pattern ACT may be disposed on the substrate SUB. For example, the active pattern ACT may be disposed on the buffer layer BUF. The active pattern ACT may include a silicon semiconductor material, an oxide semiconductor material, an organic semiconductor material, or the like. In an embodiment, the active pattern ACT may include a silicon semiconductor material. The silicon semiconductor material may include amorphous silicon, polycrystalline silicon, or the like. The active pattern ACT may include a source area, a drain area, and a channel area between the source area and the drain area.

The first gate insulating layer GI1 may be disposed on the buffer layer BUF. The first gate insulating layer GI1 may cover the active pattern ACT. The first gate insulating layer GI1 may include an inorganic insulating material. Examples of the inorganic insulating material that may be used as the first gate insulating layer GI1 may include silicon oxide (SiOₓ), silicon nitride (SiNₓ), silicon oxynitride (SiOₓN_{y}), or the like. These may be used alone or in combination with each other.

The gate electrode GE may be disposed on the first gate insulating layer GI1. The gate electrode GE may overlap the active pattern ACT in a plan view. The gate electrode GE may overlap the channel area of the active pattern ACT. The gate electrode GE may include a conductive material such as a metal, an alloy, a conductive metal nitride, a conductive metal oxide, a transparent conductive oxide, or the like. Examples of the conductive material may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second gate insulating layer GI2 may be disposed on the first gate insulating layer GI1. The second gate insulating layer GI2 may cover the gate electrode GE. The second gate insulating layer GI2 may include an inorganic insulating material. Examples of the inorganic insulating material that may be used as the second gate insulating layer GI2 may include silicon oxide (SiOₓ), silicon nitride (SiNₓ), silicon oxynitride (SiOₓN_{y}), or the like. These may be used alone or in combination with each other.

The capacitor electrode CAPE may be disposed on the second gate insulating layer GI2. The capacitor electrode CAPE may overlap the gate electrode GE in a plan view. The capacitor electrode CAPE and the gate electrode GE may form the storage capacitor CST of FIGS. 3A and 3B. The capacitor electrode CAPE may include a conductive material such as a metal, an alloy, a conductive metal nitride, a conductive metal oxide, a transparent conductive oxide, or the like. These may be used alone or in combination with each other.

The inter-layer insulating layer ILD may be disposed on the second gate insulating layer GI2. The inter-layer insulating layer ILD may cover the capacitor electrode CAPE. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), or the like. These may be used alone or in combination with each other.

The source electrode SE and the drain electrode DE may be disposed on the inter-layer insulating layer ILD. The source electrode SE may be connected to the source area of the active pattern ACT through a contact hole that penetrates the first gate insulating layer GI1, the second gate insulating layer GI2, and the inter-layer insulating layer ILD. The drain electrode DE may be connected to the drain area of the active pattern ACT through a contact hole that penetrates the first gate insulating layer GI1, the second gate insulating layer GI2, and the inter-layer insulating layer ILD. Each of the source electrode SE and the drain electrode DE may include a conductive material such as a metal, an alloy, a conductive metal nitride, a conductive metal oxide, a transparent conductive oxide, or the like. These may be used alone or in combination with each other.

Accordingly, the thin film transistor TR including the active pattern ACT, the gate electrode GE, the source electrode SE, and the drain electrode DE may be formed on the substrate SUB.

The first via-insulating layer VIA1 may be disposed on the inter-layer insulating layer ILD. For example, the first via-insulating layer VIA1 may be disposed on the inter-layer insulating layer ILD with a relatively thick thickness to sufficiently cover the source electrode SE and the drain electrode DE. The first via-insulating layer VIA1 may include an organic insulating material. Examples of the organic insulating material that may be used as the first via-insulating layer VIA1 may include a polyacryl-based resin, a polyimide-based resin, a polyamide-based resin, a siloxane-based resin, an acryl-based resin, an epoxy-based resin, or the like. These may be used alone or in combination with each other.

The connection electrode LCE may be disposed on the first via-insulating layer VIA1. The connection electrode LCE may be connected to the source electrode SE or the drain electrode DE through a contact hole that penetrates the first via-insulating layer VIA1. Accordingly, the connection electrode LCE may electrically connect the thin-film transistor TR and the light-emitting element LD. The connection electrode LCE may include a conductive material such as a metal, an alloy, a conductive metal nitride, a conductive metal oxide, a transparent conductive oxide, or the like. These may be used alone or in combination with each other.

The second via-insulating layer VIA2 may be disposed on the first via-insulating layer VIA1. The second via-insulating layer VIA2 may be disposed on the first via-insulating layer VIA1 with a relatively thick thickness to sufficiently cover the connection electrode LCE. The second via-insulating layer VIA2 may include an organic insulating material. Examples of the organic insulating material that may be used as the second via-insulating layer VIA2 may include a polyacryl-based resin, a polyimide-based resin, a polyamide-based resin, a siloxane-based resin, an acryl-based resin, an epoxy-based resin, or the like. These may be used alone or in combination with each other.

The pixel electrode PE may be disposed on the second via-insulating layer VIA2. The pixel electrode PE may be connected to the connection electrode LCE through a contact hole that penetrates the second via-insulating layer VIA2. The pixel electrode PE may include a conductive material such as a metal, an alloy, a conductive metal nitride, a conductive metal oxide, a transparent conductive oxide, or the like. These may be used alone or in combination with each other. For example, the pixel electrode PE may function as the anode.

The pixel defining layer PDL may be disposed on the second via-insulating layer VIA2. The pixel defining layer PDL may cover an edge of the pixel electrode PE, and may expose an upper surface of the pixel electrode PE. The pixel defining layer PDL may include an organic insulating material and/or an inorganic insulating material.

In an embodiment, the spacer SPA may be disposed on the pixel defining layer PDL. The spacer SPA may limit and/or prevent sagging of a fine metal mask (FMM). In addition, the spacer SPA may limit and/or prevent imprinting by the fine metal mask. The spacer SPA may include an organic insulating material. In an embodiment, the spacer SPA may be integrally formed with the pixel defining layer PDL. For example, the spacer SPA and the pixel defining layer PDL may be simultaneously formed using a halftone mask process.

The light-emitting layer EML may be disposed on the pixel electrode PE. The light-emitting layer EML may emit light having a specific color (e.g., red, green, or blue, but not limited thereto). In an embodiment, the light-emitting layer EML may include at least one of an organic light-emitting material and a quantum dot. For example, the light-emitting layer EML may have a single-layer structure including one light-emitting structure. However, the present disclosure is not necessarily limited thereto, and the light-emitting layer EML may have a tandem structure including a plurality of light-emitting structures.

The common electrode CE may be disposed on the pixel defining layer PDL, the spacer SPA, and the light-emitting layer EML. The common electrode CE may cover the pixel defining layer PDL, the spacer SPA, and the light-emitting layer EML. The common electrode CE may be disposed along the profile of the pixel defining layer PDL, the spacer SPA, and the light-emitting layer EML with a substantially uniform thickness. The common electrode CE may include a conductive material such as a metal, an alloy, a conductive metal nitride, a conductive metal oxide, a transparent conductive oxide, or the like. These may be used alone or in combination with each other. For example, the common electrode CE may function as the cathode.

Accordingly, the light-emitting element LD including the pixel electrode PE, the light-emitting layer EML, and the common electrode CE may be formed on the second via-insulating layer VIA2.

The encapsulation substrate ENC may be disposed on the common electrode CE. The encapsulation substrate ENC may limit and/or prevent impurities, moisture, or the like from penetrating into the light-emitting element LD from the outside. The encapsulation substrate ENC may include a transparent material. For example, the encapsulation substrate ENC may include glass or plastic.

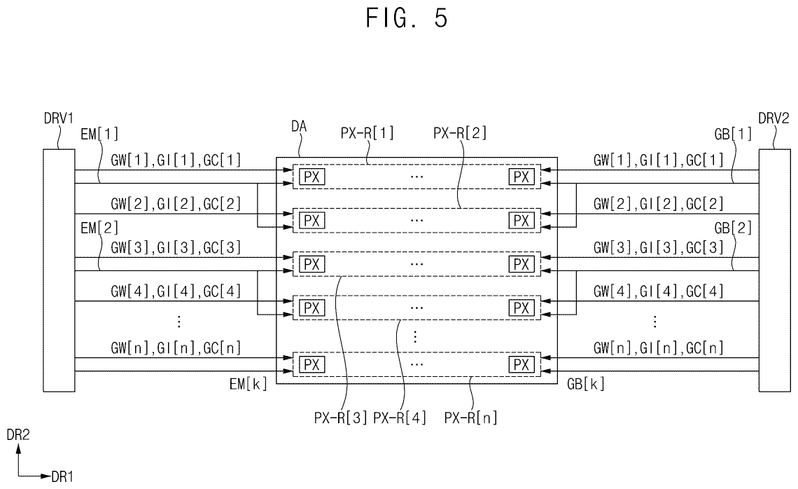

FIG. 5 is a diagram illustrating an example of signals applied to a pixel included in the display device of FIG. 1.

Referring to FIG. 5, the pixels PX may be disposed in the display area DA. For example, a plurality of pixel rows PX-R[1], PX-R[2], . . . , PX-R[n] may be disposed in the display area DA. Each of the plurality of pixel rows PX-R[1], PX-R[2], . . . , PX-R[n] may include the pixels PX that are repeatedly disposed along the first direction DR1. The plurality of pixel rows PX-R[1], PX-R[2], . . . , PX-R[n] may be arranged along the second direction DR2.

For example, the first driver DRV1 may be disposed in the peripheral area (PA, see FIG. 2) adjacent to a left side of the display area DA, and the second driver DRV2 may be disposed in the peripheral area adjacent to a right side of the display area DA.

In an embodiment, each of the first driver DRV1 and the second driver DRV2 may output write gate signals GW[1], GW[2], . . . , GW[n], initialization gate signals GI[1], GI[2], . . . , GI[n], and compensation gate signals GC[1], GC[2], . . . , GC[n] to the plurality of pixel rows PX-R[1], PX-R[2], . . . , PX-R[n]. In this case, the write gate signal GW, the initialization gate signal GI, and the compensation gate signal GC may be output from opposite sides of the display area DA.

In an embodiment, the first driver DRV1 may output emission signals EM[1], EM[2], . . . , EM[k] to the plurality of pixel rows PX-R[1], PX-R[2], . . . , PX-R[n], and the second driver DRV2 may output bias gate signals GB[1], GB[2], . . . , GB[k] to the plurality of pixel rows PX-R[1], PX-R[2], . . . , PX-R[n]. In this case, the emission signal EM and the bias gate signal GB may be output only from one side of the display area DA. For example, the first driver DRV1 may output the emission signal EM from the left side of the display area DA, and the second driver DRV2 may not output the emission signal EM. In addition, the second driver DRV2 may output the bias gate signal GB from the right side of the display area DA, and the first driver DRV1 may not output the bias gate signal GB.

In FIG. 5, the emission signal EM and the bias gate signal GB are illustrated as being output only from one side of the display area DA, but the present disclosure is not necessarily limited thereto. For example, at least one scan signal among the write gate signal GW, the initialization gate signal GI, and the compensation gate signal GC may be output only from a first side of the display area DA, and may not be output from a second side opposite to the first side of the display area DA.

In an embodiment, a first write gate signal GW[1], a first initialization gate signal GI[1], and a first compensation gate signal GC[1] may be applied to a first pixel row PX-R[1]. A second write gate signal GW[2], a second initialization gate signal GI[2], and a second compensation gate signal GC[2] may be applied to a second pixel row PX-R[2]. A third write gate signal GW[3], a third initialization gate signal GI[3], and a third compensation gate signal GC[3] may be applied to a third pixel row PX-R[3]. A fourth write gate signal GW[4], a fourth initialization gate signal GI[4], and a fourth compensation gate signal GC[4] may be applied to a fourth pixel row PX-R[4]. That is, an N-th write gate signal GW[n], an N-th initialization gate signal GI[n], and an N-th compensation gate signal GC[n] may be applied to an N-th pixel row PX-R[n].

In an embodiment, a first emission signal EM[1] may be applied to the first pixel row PX-R[1] and the second pixel row PX-R[2]. The first pixel row PX-R[1] and the second pixel row PX-R[2] may receive the first emission signal EM[1] having the same timing. A second emission signal EM[2] may be applied to the third pixel row PX-R[3] and the fourth pixel row PX-R[4]. The third pixel row PX-R[3] and the fourth pixel row PX-R[4] may receive the second emission signal EM[2] having the same timing. In this case, the timing of the first emission signal EM[1] and the timing of the second emission signal EM[2] may be different from each other. A k-th emission signal EM[k] may be applied to an (N-1)-th pixel row and the N-th pixel row PX-R[n]. The (N-1)-th pixel row and the N-th pixel row PX-R[n] may receive the K-th emission signal EM[k] having the same timing.

In an embodiment, a first bias gate signal GB[1] may be applied to the first pixel row PX-R[1] and the second pixel row PX-R[2]. The first pixel row PX-R[1] and the second pixel row PX-R[2] may receive the first bias gate signal GB[1] having the same timing. A second bias gate signal GB[2] may be applied to the third pixel row PX-R[3] and the fourth pixel row PX-R[4]. The third pixel row PX-R[3] and the fourth pixel row PX-R[4] may receive the second bias gate signal GB[2] having the same timing. In this case, the timing of the first bias gate signal GB[1] and the timing of the second bias gate signal GB[2] may be different from each other. A k-th bias gate signal GB[k] may be applied to the (N-1)-th pixel row and the N-th pixel row PX-R[n]. The (N-1)-th pixel row and the N-th pixel row PX-R[n] may receive the K-th bias gate signal GB[k] having the same timing.

FIG. 6 is an enlarged plan view illustrating the area A of FIG. 2. FIG. 7 is a cross-sectional view taken along the line III-III′ of FIG. 6. Hereinafter, redundant descriptions of the cross-sectional structure of the display area DA described above with reference to FIG. 4 are omitted or simplified.

Referring to FIGS. 6 and 7, the display device DD may further include a first data bypass line DCL1, a second data bypass line DCL2, a constant voltage line CVL, a scan bypass line SCL, and first to third dam portions DM1, DM2, and DM3 in a second area A2.

As the display panel (100, see FIG. 2) includes the hole area HA and the display area DA surrounding the hole area HA in a plan view, the substrate SUB may include the hole area HA and the display area DA surrounding the hole area HA in a plan view.

The hole area HA may include a first area A1 and the second area A2. The first area A1 may be an area in which the through hole HL is defined. That is, the first area A1 may entirely overlap the through hole HL. As illustrated in FIG. 7, the through hole HL may penetrate the buffer layer BUF, the first gate insulating layer GI1, the second gate insulating layer GI2, the inter-layer insulating layer ILD, the first via-insulating layer VIA1, and the second via-insulating layer VIA2. As illustrated in FIG. 7, a filling layer FIL may be disposed on the substrate SUB in the first area A1. In addition, the filling layer FIL may partially overlap the second area A2. The filling layer FIL may fill an interior of the through hole HL.

As described above, the functional module CAM (e.g., a camera or the like) for capturing an external image or determining the accessibility of an external object may overlap the hole area HA. For example, the functional module CAM may be disposed under the substrate SUB and may overlap the first area A1. The filling layer FIL may fill the interior of the through hole HL, and may be positioned on the functional module CAM. For example, the filling layer FIL may include an organic material and/or an inorganic material.

The second area A2 may surround the first area A1 in a plan view. The second area A2 may be an area between the through hole HL and the display area DA. In FIG. 6, the first area A1 is illustrated as having a circular planar shape corresponding to the shape of the through hole HL, but the present disclosure is not necessarily limited thereto.

The first data bypass line DCL1 may be disposed in the second area A2. The first data bypass line DCL1 may be connected to the data line DL extending in the second direction DR2. The data voltage (VDATA, see FIG. 3A or FIG. 3B) may be applied to the first data bypass line DCL1. The first data bypass line DCL1 may extend to bend along a border of the through hole HL. For example, a first portion of the first data bypass line DCL1 may be connected to the data line DL positioned at a lower portion of the through hole HL in a plan view, and a second portion of the first data bypass line DCL1 different from the first portion may be connected to the data line DL positioned at an upper portion of the through hole HL in a plan view.

The second data bypass line DCL2 may be disposed in the second area A2. The second data bypass line DCL2 may be connected to the data line DL extending in the second direction DR2. The data voltage may be applied to the second data bypass line DCL2. The second data bypass line DCL2 may extend to bend along the border of the through hole HL. For example, a first portion of the second data bypass line DCL2 may be connected to the data line DL positioned at the lower portion of the through hole HL in a plan view, and a second portion of the second data bypass line DCL2 different from the first portion may be connected to the data line DL positioned at the upper portion of the through hole HL in a plan view.

In an embodiment, as illustrated in FIG. 7, the first data bypass line DCL1 and the second data bypass line DCL2 may be disposed in different layers. For example, the first data bypass line DCL1 may be disposed in the same layer as the gate electrode GE, and the second data bypass line DCL2 may be disposed in the same layer as the capacitor electrode CAPE. That is, the second gate insulating layer GI2 may cover the first data bypass line DCL1 on the first gate insulating layer GI1, and the inter-layer insulating layer ILD may cover the second data bypass line DCL2 on the second gate insulating layer GI2.

In an embodiment, the data line DL, the first data bypass line DCL1, and the second data bypass line DCL2 may be disposed in different layers. For example, the data line DL may be disposed in the same layer as the drain electrode DE or the connection electrode LCE in the display area DA, the first data bypass line DCL1 may be disposed in the same layer as the gate electrode GE in the second area A2, and the second data bypass line DCL2 may be disposed in the same layer as the capacitor electrode CAPE in the second area A2.

In FIGS. 6 and 7, two first data bypass lines DCL1 and three second data bypass lines DCL2 are illustrated as being disposed in the second area A2, but the present disclosure is not necessarily limited thereto. The number of first data bypass lines DCL1 and the number of second data bypass lines DCL2 disposed in the second area A2 may be changed according to embodiments.

The scan bypass line SCL may be disposed in the second area A2. The scan bypass line SCL may be connected to a first scan line SL1 or a second scan line SL2 extending in the first direction DR1. In this case, the first scan line SL1 may be a line to which a first scan signal is applied from the first driver (DRV1, see FIG. 5), and the second scan line SL2 may be a line to which a second scan signal different from the first scan signal is applied from the second driver (DRV2, see FIG. 5). Each of the first scan signal and the second scan signal may include at least one scan signal selected from the write gate signal GW, the initialization gate signal GI, the compensation gate signal GC, the emission signal EM, and the bias gate signal GB of FIGS. 3A and 3B.

In an embodiment, each of the first scan line SL1 and the second scan line SL2 may be a line to which a scan signal output only from one side of the display area DA is applied. For example, as illustrated in FIG. 5, when the emission signal EM is output only from the left side of the display area DA by the first driver DRV1, and the bias gate signal GB is output only from the right side of the display area DA by the second driver DRV2, the first scan line SL1 may be a line to which the emission signal EM is applied, and the second scan line SL2 may be a line to which the bias gate signal GB is applied. However, the present disclosure is not necessarily limited thereto.

In FIG. 6, although the first scan line SL1 is illustrated as being disposed only at a left side of the through hole HL in a plan view, the first scan line SL1 may also be disposed at a right side of the through hole HL in a plan view. In addition, although the second scan line SL2 is illustrated in FIG. 6 as being disposed only at the right side of the through hole HL in a plan view, the second scan line SL2 may also be disposed at the left side of the through hole HL in a plan view.

The scan bypass line SCL may extend to bend along the border of the through hole HL. For example, a first portion of the scan bypass line SCL may be connected to the first scan line SL1 positioned at the left side of the through hole HL in a plan view, and a second portion of the scan bypass line SCL different from the first portion may be connected to the first scan line SL1 positioned at the right side of the through hole HL in a plan view. For another example, the first portion of the scan bypass line SCL may be connected to the second scan line SL2 positioned at the right side of the through hole HL in a plan view, and the second portion of the scan bypass line SCL different from the first portion may be connected to the second scan line SL2 positioned at the left side of the through hole HL in a plan view.

In an embodiment, as illustrated in FIG. 7, the scan bypass line SCL, the first data bypass line DCL1, and the second data bypass line DCL2 may be disposed in different layers. In an embodiment, the scan bypass line SCL may be disposed above the first data bypass line DCL1 and the second data bypass line DCL2. For example, the scan bypass line SCL may be disposed in the same layer as the connection electrode LCE, the first data bypass line DCL1 may be disposed in the same layer as the gate electrode GE, and the second data bypass line DCL2 may be disposed in the same layer as the capacitor electrode CAPE.

In an embodiment, the scan bypass line SCL, the first scan line SL1, and the second scan line SL2 may be disposed in different layers. For example, the scan bypass line SCL may be disposed in the same layer as the connection electrode LCE in the second area A2, the first scan line SL1 may be disposed in the same layer as the gate line GE or the capacitor electrode CAPE, and the second scan line SL2 may be disposed in the same layer as the gate line GE or the capacitor electrode CAPE.

In an embodiment, the scan bypass line SCL may overlap the second data bypass line DCL2 in a plan view. However, the present disclosure is not necessarily limited thereto.

In FIGS. 6 and 7, three scan bypass lines SCLs are illustrated as being disposed in the second area A2, but the present disclosure is not necessarily limited thereto. The number of the scan bypass lines SCL disposed in the second area A2 may be changed according to embodiments.

As illustrated in FIG. 7, the constant voltage line CVL may be disposed between the second data bypass line DCL2 and the scan bypass line SCL in the second area A2. In an embodiment, the constant voltage line CVL may be disposed in the same layer as the drain electrode DE. That is, the first via-insulating layer VIA1 may cover the constant voltage line CVL on the inter-layer insulating layer ILD. The constant voltage line CVL may block electrical interference between the scan bypass line SCL to which the first scan signal or the second scan signal is applied and the first and second data bypass lines DCL1 and DCL2 to which the data voltage is applied. For example, the driving voltage (ELVDD, see FIG. 3A or FIG. 3B) may be applied to the constant voltage line CVL, but the present disclosure is not necessarily limited thereto.

In an embodiment, the constant voltage line CVL may overlap the scan bypass line SCL in a plan view. In addition, the constant voltage line CVL may overlap the data bypass line (e.g., the second data bypass line DCL2) in a plan view.

The second via-insulating layer VIA2 may be disposed on the first via-insulating layer VIA1. The second via-insulating layer VIA2 may cover the scan bypass line SCL in the second area A2. In an embodiment, an upper surface of the second via-insulating layer VIA2 may have an uneven structure CCS in the second area A2. In this case, the upper surface of the second via-insulating layer VIA2 may include a concave portion and a convex portion defining the uneven structure CCS. The concave portion may be defined as a portion of the upper surface of the second via-insulating layer VIA2 recessed toward the substrate SUB. An upper surface of the convex portion may be positioned at the substantially same level as the upper surface of the second via-insulating layer VIA2 in the display area DA. The concave portion and the convex portion may be alternately arranged along one direction.

In an embodiment, the convex portion may overlap the scan bypass line SCL in a plan view. Accordingly, the convex portion may increase a separation distance between the scan bypass line SCL and the common electrode CE. For example, as illustrated in FIG. 7, all of the scan bypass lines SCL may overlap the convex portion in a plan view. However, the present disclosure is not necessarily limited thereto.

The first to third dam portions DM1, DM2, and DM3 may be disposed on the second via-insulating layer VIA2 in the second area A2. The first to third dam portions DM1, DM2, and DM3 may be spaced apart from each other. For example, the first dam portion DM1 may be disposed in the second area A2 adjacent to the display area DA, the second dam portion DM2 may be disposed in the second area A2 adjacent to the first area A1 in which the through hole HL is defined, and the third dam portion DM3 may be disposed between the first dam portion DM1 and the second dam portion DM2. The third dam portion DM3 may overlap the uneven structure CCS of the second via-insulating layer VIA2.

In an embodiment, the third dam portion DM3 may overlap the convex portion of the uneven structure CCS of the second via-insulating layer VIA2. However, the present disclosure is not necessarily limited thereto.

In an embodiment, the third dam portion DM3 may overlap the scan bypass line SCL in a plan view. However, the present disclosure is not necessarily limited thereto.

The first to third dam portions DM1, DM2, and DM3 may limit and/or prevent the filling layer FIL filling inside the through hole HL from overflowing into the display area DA. For example, in a process of filling the filling layer FIL inside the through hole HL, the second dam portion DM2 closest to the filling layer FIL may first limit and/or prevent the filling layer FIL from overflowing into the display area DA. Even if a fluid included in the filling layer FIL overflows the second dam portion DM2, the first dam portion DM1 and the third dam portion DM3 may limit and/or prevent the fluid from overflowing into the display area DA. In addition, as the upper surface of the second via-insulating layer VIA2 includes the concave portion, even if the fluid included in the filling layer FIL overflows the second dam portion DM2, the concave portion of the second via-insulating layer VIA2 may accommodate a relatively large amount of the fluid overflowing the second dam portion DM2.

Each of the first to third dam portions DM1, DM2, and DM3 may have a single-layer structure or a multi-layer structure. In an embodiment, each of the first to third dam portions DM1, DM2, and DM3 may have a multi-layer structure. For example, each of the first to third dam portions DM1, DM2, and DM3 may include a first dam layer DL1 and a second dam layer DL2 disposed on the first dam layer DL1. The first dam layer DL1 and the pixel defining layer PDL may include the same material and may be formed through the same process. The second dam layer DL2 and the spacer SPA may include the same material and may be formed through the same process. However, the present disclosure is not necessarily limited thereto.

The common electrode CE may continuously extend along the display area DA and the second area A2. The common electrode CE may cover the first to third dam portions DM1, DM2, and DM3 in the second area A2. The common electrodes CE may be disposed along the profiles of the first to third dam portions DM1, DM2, and DM3 and the second via-insulating layer VIA2 in the second area A2. That is, in an embodiment, the common electrode CE may be disposed along the profiles of the uneven structure CCS of the second via-insulating layer VIA2 and the third dam portion DM3 in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE. Accordingly, the scan bypass line SCL may not be electrically connected to the common electrode CE. That is, a lighting defect caused by the scan bypass line SCL being electrically shorted with the common electrode CE may be limited and/or prevented. As a result, the display quality of the display device DD may be improved.

The encapsulation substrate ENC may be disposed on the common electrode CE and the filling layer FIL. The encapsulation substrate ENC may be entirely disposed over the first area A1, the second area A2, and the display area DA.

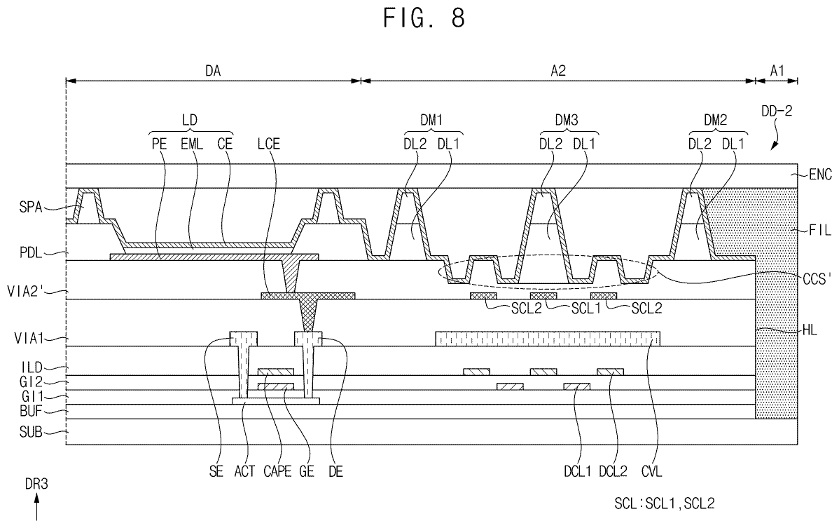

FIG. 8 is a cross-sectional view illustrating a display device according to an embodiment of the present disclosure.

Referring to FIG. 8, a display device DD-2 according to an embodiment of the present disclosure may include a substrate SUB, a buffer layer BUF, a first gate insulating layer GI1, a first data bypass line DCL1, a second gate insulating layer GI2, a second data bypass line DCL2, an inter-layer insulating layer ILD, a constant voltage line CVL, a first via-insulating layer VIA1, a scan bypass line SCL, a second via-insulating layer VIA2′, first to third dam portions DM1, DM2, and DM3, a common electrode CE, and an encapsulation substrate ENC in a second area A2.

The display device DD-2 may be substantially the same as the display device DD described above with reference to FIGS. 1 to 7, except that the third dam portion DM3 may overlap a concave portion of an uneven structure CCS′ of the second via-insulating layer VIA2′. Although not illustrated in FIG. 8, the display device DD-2 may further include the functional module CAM of FIG. 7. Hereinafter, redundant descriptions of the display device DD described above with reference to FIGS. 1 to 7 are omitted or summarized.

The second via-insulating layer VIA2′ may be disposed on the first via-insulating layer VIA1. The second via-insulating layer VIA2′ may cover the scan bypass line SCL in the second area A2. In an embodiment, an upper surface of the second via-insulating layer VIA2′ may have the uneven structure CCS′0 in the second area A2. In this case, the upper surface of the second via-insulating layer VIA2′ may include the concave portion and a convex portion defining the uneven structure CCS′. The concave portion may be defined as a portion of the upper surface of the second via-insulating layer VIA2′ recessed toward the substrate SUB. An upper surface of the convex portion may be positioned at the substantially same level as the upper surface of the second via-insulating layer VIA2′ in the display area DA.

In an embodiment, the scan bypass line SCL may be provided in a plural, and the scan bypass lines SCL may include a first scan bypass line SCL1 and a second scan bypass line SCL2. The convex portion may overlap the second scan bypass line SCL2 in a plan view. Accordingly, the convex portion may increase a separation distance between the second scan bypass line SCL2 and the common electrode CE. That is, as illustrated in FIG. 8, the second scan bypass line SCL2 may overlap the convex portion in a plan view. The first scan bypass line SCL1 may be spaced apart from the convex portion in a plan view, but may overlap the third dam portion DM3 in a plan view.

The first to third dam portions DM1, DM2, and DM3 may be disposed on the second via-insulating layer VIA2′ in the second area A2. The first dam portion DM1 may be disposed in the second area A2 adjacent to the display area DA, the second dam portion DM2 may be disposed in the second area A2 adjacent to the first area A1 in which the through hole HL is defined, and the third dam portion DM3 may be disposed between the first dam portion DM1 and the second dam portion DM2. The third dam portion DM3 may overlap the uneven structure CCS′ of the second via-insulating layer VIA2′.

In an embodiment, the third dam portion DM3 may overlap the concave portion of the uneven structure CCS′ of the second via-insulating layer VIA2′, and may overlap the first scan bypass line SCL1 in a plan view.

The common electrode CE may continuously extend along the display area DA and the second area A2. The common electrode CE may be disposed along the profiles of the first to third dam portions DM1, DM2, and DM3 and the second via-insulating layer VIA2′ in the second area A2. That is, in an embodiment, the common electrode CE may be disposed along the profiles of the uneven structure CCS′ of the second via-insulating layer VIA2′ and the third dam portion DM3 in the second area A2.

The convex portion defining the uneven structure CCS′ of the second via-insulating layer VIA2′ may overlap the second scan bypass line SCL2 in a plan view. As the common electrode CE is disposed along the profile of the convex portion of the uneven structure CCS′, the convex portion may increase a separation distance between the second scan bypass line SCL2 and the common electrode CE.

In addition, the third dam portion DM3 may overlap the concave portion of the uneven structure CCS′ of the second via-insulating layer VIA2′. In this case, the first scan bypass line SCL1 may overlap the concave portion of the uneven structure CCS′ of the second via-insulating layer VIA2′ and the third dam portion DM3 in a plan view. As the common electrode CE is disposed along the profile of the third dam portion DM3, the third dam portion DM3 may increase a separation distance between the first scan bypass line SCL1 and the common electrode CE.

Accordingly, the scan bypass lines SCL may not be electrically connected to the common electrode CE. That is, a lighting defect caused by the scan bypass lines SCL being electrically shorted with the common electrode CE may be limited and/or prevented, and the display quality of the display device DD-2 may be improved.

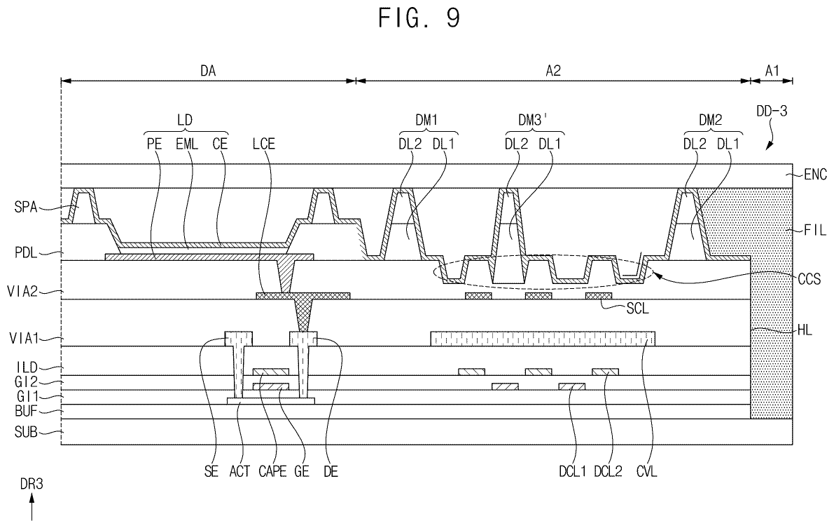

FIG. 9 is a cross-sectional view illustrating a display device according to an embodiment of the present disclosure.

Referring to FIG. 9, a display device DD-3 according to an embodiment of the present disclosure may include a substrate SUB, a buffer layer BUF, a first gate insulating layer GI1, a first data bypass line DCL1, a second gate insulating layer GI2, a second data bypass line DCL2, an inter-layer insulating layer ILD, a constant voltage line CVL, a first via-insulating layer VIA1, a scan bypass line SCL, a second via-insulating layer VIA2, first to third dam portions DM1, DM2, and DM3′, a common electrode CE, and an encapsulation substrate ENC in a second area A2.

The display device DD-3 may be substantially the same as the display device DD described above with reference to FIGS. 1 to 7, except that the third dam portion DM3′ may overlap a concave portion of an uneven structure CCS of the second via-insulating layer VIA2, and may be spaced apart from the scan bypass line SCL in a plan view. Although not illustrated in FIG. 9, the display device DD-3 may further include the functional module CAM of FIG. 7. Hereinafter, redundant descriptions of the display device DD described above with reference to FIGS. 1 to 7 are omitted or summarized.

The second via-insulating layer VIA2 may be disposed on the first via-insulating layer VIA1. The second via-insulating layer VIA2 may cover the scan bypass line SCL in the second area A2. In an embodiment, an upper surface of the second via-insulating layer VIA2 may have the uneven structure CCS in the second area A2. In this case, the upper surface of the second via-insulating layer VIA2 may include the concave portion and a convex portion defining the uneven structure CCS.

In an embodiment, the convex portion may overlap the scan bypass line SCL in a plan view. Accordingly, the convex portion may increase a separation distance between the scan bypass line SCL and the common electrode CE. For example, as illustrated in FIG. 9, all of the scan bypass lines SCL may overlap the convex portion in a plan view.

The first to third dam portions DM1, DM2, and DM3′ may be disposed on the second via-insulating layer VIA2 in the second area A2. The first dam portion DM1 may be disposed in the second area A2 adjacent to the display area DA, the second dam portion DM2 may be disposed in the second area A2 adjacent to the first area A1 in which the through hole HL is defined, and the third dam portion DM3′ may be disposed between the first dam portion DM1 and the second dam portion DM2. The third dam portion DM3′ may overlap the uneven structure CCS of the second via-insulating layer VIA2.

In an embodiment, the third dam portion DM3′ may overlap the concave portion of the uneven structure CCS of the second via-insulating layer VIA2, and may be spaced apart from the scan bypass line SCL in a plan view.

The common electrode CE may be disposed along the profiles of the first to third dam portions DM1, DM2, and DM3′ and the second via-insulating layer VIA2 in the second area A2. That is, in an embodiment, the common electrode CE may be disposed along the profiles of the uneven structure CCS of the second via-insulating layer VIA2 and the third dam portion DM3′ in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE. Accordingly, a lighting defect caused by the scan bypass line SCL being electrically shorted with the common electrode CE may be limited and/or prevented, and the display quality of the display device DD-3 may be improved.

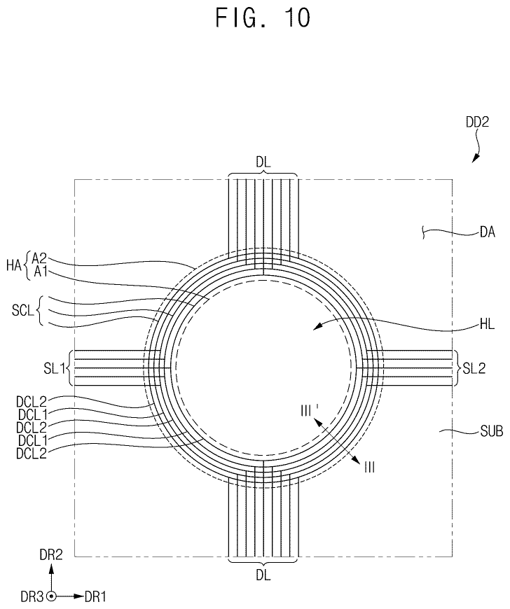

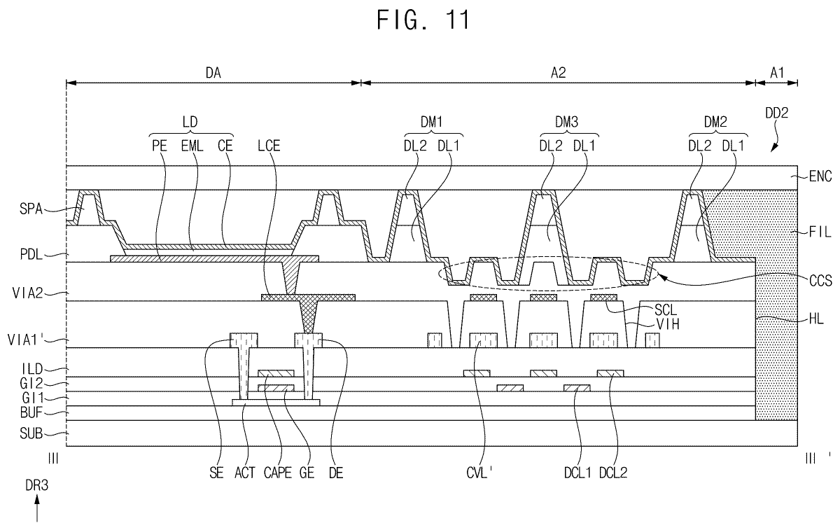

FIG. 10 is a plan view illustrating a display device according to an embodiment of the present disclosure. FIG. 11 is a cross-sectional view taken along the line III-III′ of FIG. 10.

Referring to FIGS. 10 and 11, a display device DD2 according to an embodiment of the present disclosure may include a substrate SUB, a buffer layer BUF, a first gate insulating layer GI1, a first data bypass line DCL1, a second gate insulating layer GI2, a second data bypass line DCL2, an inter-layer insulating layer ILD, a constant voltage pattern CVL′, a first via-insulating layer VIA1′, a scan bypass line SCL, a second via-insulating layer VIA2, first to third dam portions DM1, DM2, and DM3, a common electrode CE, and an encapsulation substrate ENC in a second area A2.

The display device DD2 may be substantially the same as the display device DD described above with reference to FIGS. 1 to 7, except that a via-hole VIH that penetrates the first via insulating layer VIA1′ is defined and the second via-insulating layer VIA2 is disposed along the profile of the first via-insulating layer VIA1′. Although not illustrated in FIG. 11, the display device DD2 may further include the functional module CAM of FIG. 7. Hereinafter, redundant descriptions of the display device DD described above with reference to FIGS. 1 to 7 are omitted or summarized.

The first via-insulating layer VIA1′ may be disposed on the inter-layer insulating layer ILD. In an embodiment, via-holes VIH that penetrates the first via insulating layer VIA1′ may be defined in the second area A2. The via-holes VIH may be spaced apart from each other. In a process of forming the via-holes VIH, a constant voltage line may be patterned into a plurality of constant voltage patterns CVL′. That is, the constant voltage patterns CVL′ may be spaced apart from each other, and the via-hole VIH may be positioned between the constant voltage patterns CVL′. The first via-insulating layer VIA1′ may cover the constant voltage patterns CVL′.

The scan bypass line SCL may be disposed on the first via-insulating layer VIA1′ in the second area A2. For example, the scan bypass line SCL may be disposed on an upper surface of the first via-insulating layer VIA′ in the second area A2, and may be disposed between the via-holes VIH. In an embodiment, the scan bypass line SCL may overlap the constant voltage pattern CVL′ in a plan view.

The second via-insulating layer VIA2 may be disposed on the first via-insulating layer VIA1′. The second via-insulating layer VIA2 may cover the scan bypass line SCL in the second area A2. In an embodiment, the second via-insulating layer VIA2 may be disposed along the profile of the first via-insulating layer VIA1′. That is, as the via-holes VIH are defined in the first via-insulating layer VIA1, an upper surface of the second via-insulating layer VIA2 disposed along the profile of the first via-insulating layer VIA1′ may have an uneven structure CCS. In this case, the upper surface of the second via-insulating layer VIA2 may include a concave portion and a convex portion defining the uneven structure CCS. The concave portion may be defined as a portion of the upper surface of the second via-insulating layer VIA2 recessed toward the substrate SUB. In an embodiment, the concave portion may overlap the via-hole VIH in a plan view. An upper surface of the convex portion may be positioned at the substantially same level as the upper surface of the second via-insulating layer VIA2 in the display area DA. The concave portion and the convex portion may be alternately arranged along one direction.

In an embodiment, the convex portion may overlap scan bypass line SCL in a plan view. For example, as illustrated in FIG. 11, all of the scan bypass lines SCL may overlap the convex portion in a plan view. However, the present disclosure is not necessarily limited thereto.

The first to third dam portions DM1, DM2, and DM3 may be disposed on the second via-insulating layer VIA2 in the second area A2. The first to third dam portions DM1, DM2, and DM3 may be spaced apart from each other. The third dam portion DM3 may be positioned between the first dam portion DM1 and the second dam portion DM2. The third dam portion DM3 may overlap the uneven structure CCS of the second via-insulating layer VIA2.

In an embodiment, the third dam portion DM3 may overlap the convex portion of the uneven structure CCS of the second via-insulating layer VIA2. However, the present disclosure is not necessarily limited thereto.

In an embodiment, the third dam portion DM3 may overlap the scan bypass line SCL in a plan view. However, the present disclosure is not necessarily limited thereto.

The common electrode CE may be disposed along the profiles of the first to third dam portions DM1, DM2, and DM3 and the second via-insulating layer VIA2 in the second area A2. That is, in an embodiment, the common electrode CE may be disposed along the profiles of the uneven structure CCS of the second via-insulating layer VIA2 and the third dam portion DM3 in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE. Accordingly, a lighting defect caused by the scan bypass line SCL being electrically shorted with the common electrode CE may be limited and/or prevented, and the display quality of the display device DD2 may be improved.

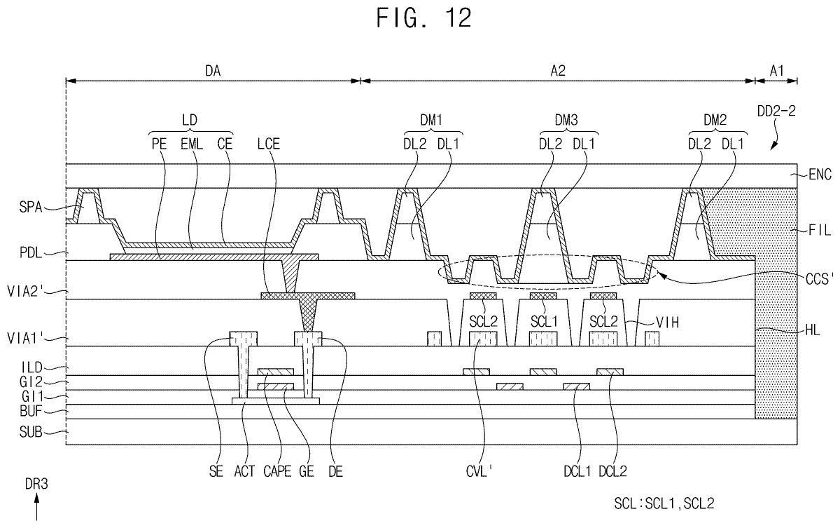

FIG. 12 is a cross-sectional view illustrating a display device according to an embodiment of the present disclosure.

Referring to FIG. 12, a display device DD2-2 according to an embodiment of the present disclosure may include a substrate SUB, a buffer layer BUF, a first gate insulating layer GI1, a first data bypass line DCL1, a second gate insulating layer GI2, a second data bypass line DCL2, an inter-layer insulating layer ILD, a constant voltage pattern CVL′, a first via-insulating layer VIA1′, a scan bypass line SCL, a second via-insulating layer VIA2′, first to third dam portions DM1, DM2, and DM3, a common electrode CE, and an encapsulation substrate ENC in a second area A2.

The display device DD2-2 may be substantially the same as the display device DD2 described above with reference to FIGS. 10 and 11, except that the third dam portion DM3 may overlap a concave portion of an uneven structure CCS′ of the second via-insulating layer VIA2′. Although not illustrated in FIG. 12, the display device DD2-2 may further include the functional module CAM of FIG. 7. Hereinafter, redundant descriptions of the display device DD2 described above with reference to FIGS. 10 and 11 are omitted or summarized.

The second via-insulating layer VIA2′ may be disposed on the first via-insulating layer VIA1′. The second via-insulating layer VIA2′ may cover the scan bypass line SCL in the second area A2. In an embodiment, the second via-insulating layer VIA2′ may be disposed along the profile of the first via-insulating layer VIA1′. That is, as via-holes VIH are defined in the first via-insulating layer VIA1′, an upper surface of the second via-insulating layer VIA2′ disposed along the profile of the first via-insulating layer VIA1′may have the uneven structure CCS′. In this case, the upper surface of the second via-insulating layer VIA2′ may include the concave portion and a convex portion defining the uneven structure CCS′.

In an embodiment, the scan bypass line SCL may be provided in a plural, and the scan bypass lines SCL may include a first scan bypass line SCL1 and a second scan bypass line SCL2. The convex portion may overlap the second scan bypass line SCL2 in a plan view. That is, as illustrated in FIG. 12, the second scan bypass line SCL2 may overlap the convex portion in a plan view. The first scan bypass line SCL1 may be spaced apart from the convex portion in a plan view, but may overlap the third dam portion DM3 in a plan view.

The first to third dam portions DM1, DM2, and DM3 may be disposed on the second via-insulating layer VIA2′ in the second area A2. The first to third dam portions DM1, DM2, and DM3 may be spaced apart from each other. The third dam portion DM3 may be positioned between the first dam portion DM1 and the second dam portion DM2. The third dam portion DM3 may overlap the uneven structure CCS′ of the second via-insulating layer VIA2′.

In an embodiment, the third dam portion DM3 may overlap the concave portion of the uneven structure CCS′ of the second via-insulating layer VIA2′, and may overlap the first scan bypass line SCL1 in a plan view.

The common electrode CE may be disposed along the profiles of the first to third dam portions DM1, DM2, and DM3 and the second via-insulating layer VIA2′ in the second area A2. That is, in an embodiment, the common electrode CE may be disposed along the profiles of the uneven structure CC′ of the second via-insulating layer VIA2′ and the third dam portion DM3 in the second area A2.

The convex portion defining the uneven structure CCS′ of the second via-insulating layer VIA2′ may overlap the second scan bypass line SCL2 in a plan view. As the common electrode CE is disposed along the profile of the convex portion of the uneven structure CCS′, the convex portion may increase a separation distance between the second scan bypass line SCL2 and the common electrode CE. In addition, the third dam portion DM3 may overlap the concave portion of the uneven structure CCS′ of the second via-insulating layer VIA2′. In this case, the first scan bypass line SCL1 may overlap the concave portion of the uneven structure CCS′ of the second via-insulating layer VIA2′ and the third dam portion DM3 in a plan view. As the common electrode CE is disposed along the profile of the third dam portion DM3, the third dam portion DM3 may increase a separation distance between the first scan bypass line SCL1 and the common electrode CE. Accordingly, a lighting defect caused by the scan bypass lines SCL being electrically shorted with the common electrode CE may be limited and/or prevented, and the display quality of the display device DD2-2 may be improved.

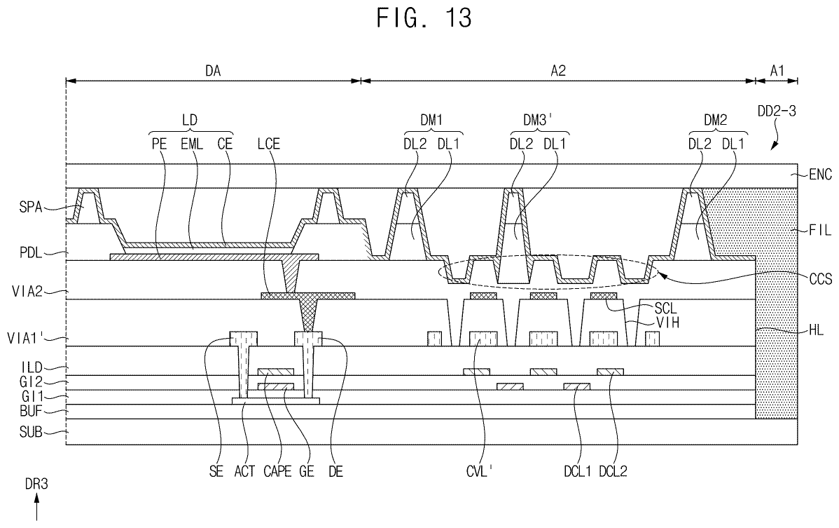

FIG. 13 is a cross-sectional view illustrating a display device according to an embodiment of the present disclosure.

Referring to FIG. 13, a display device DD2-3 according to an embodiment of the present disclosure may include a substrate SUB, a buffer layer BUF, a first gate insulating layer GI1, a first data bypass line DCL1, a second gate insulating layer GI2, a second data bypass line DCL2, an inter-layer insulating layer ILD, a constant voltage pattern CVL′, a first via-insulating layer VIA1′, a scan bypass line SCL, a second via-insulating layer VIA2, first to third dam portions DM1, DM2, and DM3′, a common electrode CE, and an encapsulation substrate ENC in a second area A2.

The display devices DD2-3 may be substantially the same as the display device DD2 described above with reference to FIGS. 10 and 11, except that the third dam portion DM3′ overlaps a concave portion of an uneven structure CCS of the second via-insulating layer VIA2 and is spaced apart from the scan bypass line SCL in a plan view. Although not illustrated in FIG. 13, the display devices DD2-3 may further include the functional module CAM of FIG. 7. Hereinafter, redundant descriptions of the display device DD2 described above with reference to FIGS. 10 and 11 are omitted or summarized.

The second via-insulating layer VIA2 may be disposed on the first via-insulating layer VIA1′. The second via-insulating layer VIA2 may cover the scan bypass line SCL in the second area A2. In an embodiment, the second via-insulating layer VIA2 may be disposed along the profile of the first via-insulating layer VIA1′. That is, as via-holes VIH are defined in the first via-insulating layer VIA′, an upper surface of the second via-insulating layer VIA2 disposed along the profile of the first via-insulating layer VIA′ may have the uneven structure CCS. In this case, the upper surface of the second via-insulating layer VIA2 may include the concave portion and a convex portion defining the uneven structure CCS.

In an embodiment, the convex portion may overlap the scan bypass line SCL in a plan view. For example, as illustrated in FIG. 13, all of the scan bypass lines SCL may overlap the convex portion in a plan view.

The first to third dam portions DM1, DM2, and DM3′ may be disposed on the second via-insulating layer VIA2 in the second area A2. The first to third dam portions DM1, DM2, and DM3′ may be spaced apart from each other. The third dam portion DM3′ may be positioned between the first dam portion DM1 and the second dam portion DM2. The third dam portion DM3′ may overlap the uneven structure CCS of the second via-insulating layer VIA2.

In an embodiment, the third dam portion DM3′ may overlap the concave portion of the uneven structure CCS of the second via-insulating layer VIA2, and may be spaced apart from the scan bypass line SCL in a plan view.

The common electrode CE may be disposed along the profiles of the first to third dam portions DM1, DM2, and DM3′ and the second via-insulating layer VIA2 in the second area A2. That is, in an embodiment, the common electrode CE may be disposed along the profiles of the uneven structure CCS of the second via-insulating layer VIA2 and the third dam portion DM3′ in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE. Accordingly, a lighting defect caused by the scan bypass line SCL being electrically shorted with the common electrode CE may be limited and/or prevented, and the display quality of the display devices DD2-3 may be improved.

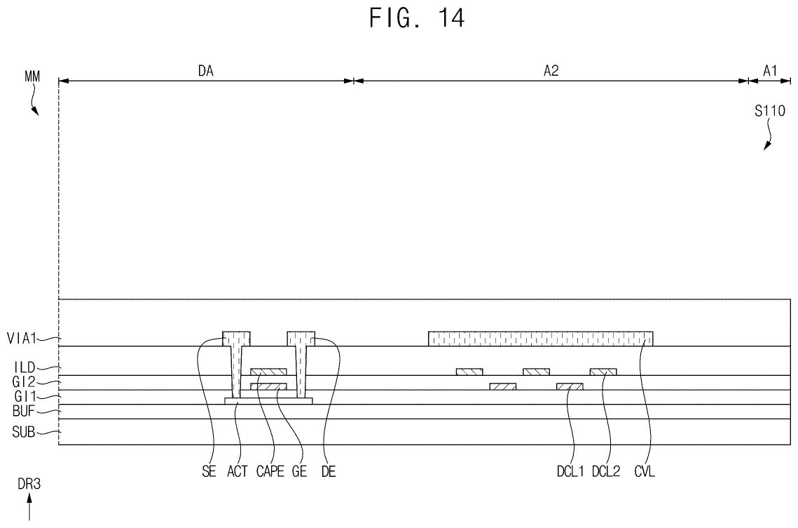

FIGS. 14, 15, 16, 17, 18, and 19 are cross-sectional views illustrating a method of manufacturing a display device according to an embodiment of the present disclosure. A method MM of manufacturing a display device described with reference to FIGS. 14 to 19 may be a method of manufacturing the display device DD described above with reference to FIG. 7. Hereinafter, redundant descriptions of the display device DD described above with reference to FIG. 7 are omitted or summarized.

Referring to FIG. 14, the thin film transistor (TR, see FIG. 4) may be formed in the display area DA on the substrate SUB, and the first data bypass line DCL1, the second data bypass line DCL2, and the constant voltage line CVL may be formed in the second area A2 on the substrate SUB (S110).

The buffer layer BUF may be formed on the substrate SUB. The active pattern ACT may be formed in the display area DA on the buffer layer BUF. The first gate insulating layer GI1 may be formed on the buffer layer BUF. The first gate insulating layer GI1 may cover the active pattern ACT.

The gate electrode GE and the first data bypass line DCL1 may be formed on the first gate insulating layer GI1. The gate electrode GE may be formed in the display area DA, and the first data bypass line DCL1 may be formed in the second area A2. In an embodiment, the gate electrode GE and the first data bypass line DCL1 may include the same material and may be formed through the same process.

The second gate insulating layer GI2 may be formed on the first gate insulating layer GI1. The second gate insulating layer GI2 may cover the gate electrode GE and the first data bypass line DCL1.

The capacitor electrode CAPE and the second data bypass line DCL2 may be formed on the second gate insulating layer GI2. The capacitor electrode CAPE may be formed in the display area DA, and the second data bypass line DCL2 may be formed in the second area A2. In an embodiment, the capacitor electrode CAPE and the second data bypass line DCL2 may include the same material and may be formed through the same process.

The inter-layer insulating layer ILD may be formed on the second gate insulating layer GI2. The inter-layer insulating layer ILD may cover the capacitor electrode CAPE and the second data bypass line DCL2.

The source electrode SE and the drain electrode DE may be formed in the display area DA on the inter-layer insulating layer ILD. The constant voltage line CVL may be formed in the second area A2 on the second data bypass line DCL2. For example, the constant voltage line CVL may be formed in the second area A2 on the inter-layer insulating layer ILD. In an embodiment, the source electrode SE, the drain electrode DE, and the constant voltage line CVL may include the same material and may be formed through the same process.

The first via-insulating layer VIA1 may be formed on the second data bypass line DCL2. For example, the first via-insulating layer VIA1 may be formed on the inter-layer insulating layer ILD. The first via-insulating layer VIA1 may cover the source electrode SE, the drain electrode DE, and the constant voltage line CVL.

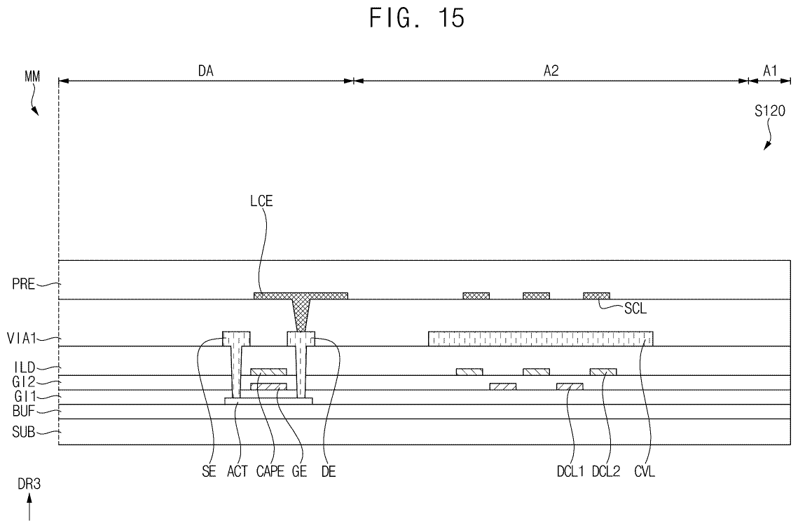

Referring to FIG. 15, the connection electrode LCE may be formed in the display area DA on the first via-insulating layer VIA1, and the scan bypass line SCL may be formed in the second area A2 on the first via-insulating layer VIA1 (S120).

In an embodiment, the scan bypass line SCL may be provided in a plural, and the plurality of scan bypass lines SCL may overlap the constant voltage line CVL in a plan view.

In an embodiment, the connection electrode LCE and the scan bypass line SCL may include the same material and may be formed through the same process.

A preliminary insulating layer PRE may be formed on the first via-insulating layer VIA1 (S120). The preliminary insulating layer PRE may cover the connection electrode LCE and the scan bypass line SCL. In an embodiment, the preliminary insulating layer PRE may include a positive photosensitive material.

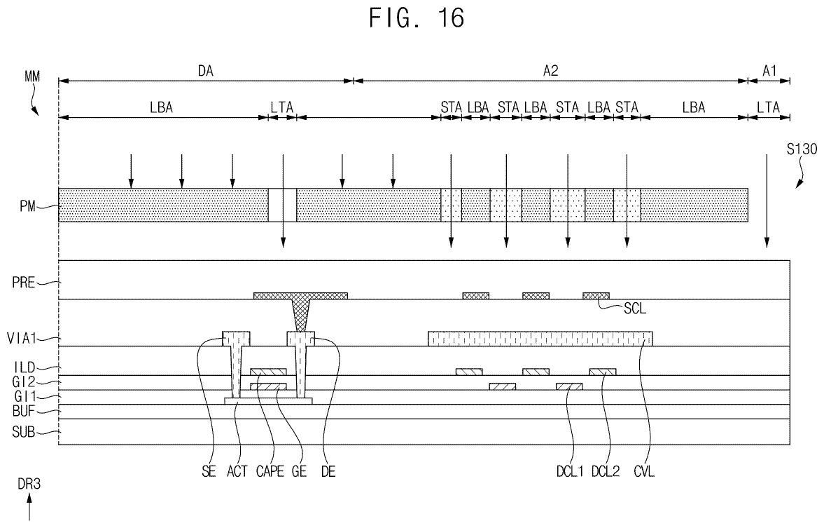

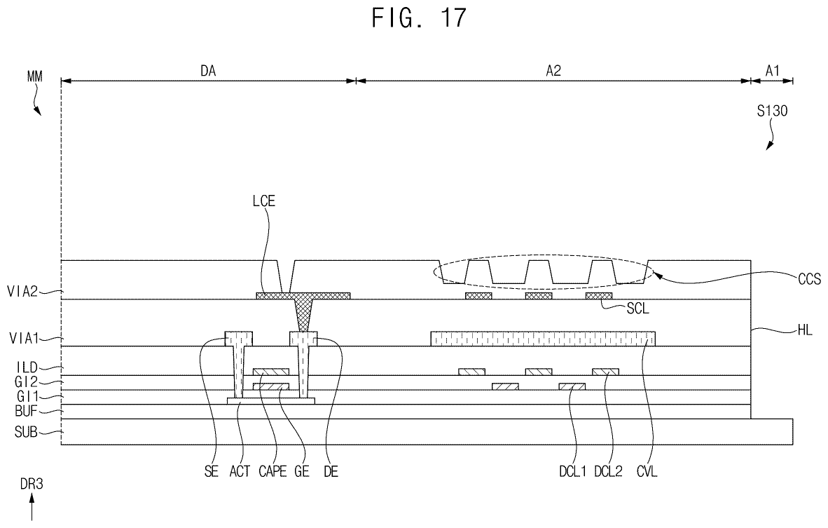

Referring to FIGS. 16 and 17, the second via-insulating layer VIA2 having the uneven structure CCS may be formed by patterning the preliminary insulating layer PRE using a photomask PM (S130).

As illustrated in FIG. 16, the photomask PM may be positioned on the preliminary insulating layer PRE. In an embodiment, the photomask PM may be a halftone mask or a slit mask. The photomask PM may include a light blocking portion LBA, a transmitting portion LTA, and a semi-transmitting portion STA. The light blocking portion LBA may block light, the transmitting portion LTA may transmit all of the light, and the semi-transmitting portion STA may transmit a portion of the light.

In an embodiment, the light blocking portion LBA may overlap the scan bypass lines SCL in a plan view, and the semi-transmitting portion STA may overlap a spaced area between the scan bypass lines SCL in a plan view. That is, the photomask PM may prevent light from reaching a portion of the preliminary insulating layer PRE overlapping the light blocking portion LBA, and may allow only a portion of the light to reach a portion of the preliminary insulating layer PRE overlapping the semi-transmitting portion STA.

In an embodiment, the transmitting portion LTA may overlap the first area A1. In addition, the transmitting portion LTA may overlap the connection electrode LCE in a plan view. That is, the photomask PM may allow all of the light to reach a portion of the preliminary insulating layer PRE overlapping the transmitting portion LTA.

For example, when the preliminary insulating layer PRE includes a positive photosensitive material, a light-blocked portion may remain in a cured state and not dissolve in a developer. In this case, a light-exposed portion may be selectively removed, and the light-blocked portion may not be removed.

That is, a portion of the preliminary insulating layer PRE overlapping the transmitting portion LTA may be completely removed by the developer. Accordingly, a contact hole exposing a portion of the connection electrode LCE in the display area DA may be formed. The contact hole may penetrate the second via-insulating layer VIA2. In addition, the through hole HL may be formed in the first area A1. The through hole HL may penetrate the buffer layer BUF, the first gate insulating layer GI1, the second gate insulating layer GI2, the inter-layer insulating layer ILD, the first via-insulating layer VIA1, and the second via-insulating layer VIA2.

A portion of the preliminary insulating layer PRE overlapping the semi-transmitting portion STA may be partially removed by the developer. Accordingly, the concave portion defining the uneven structure CCS may be formed on the upper surface of the second via-insulating layer VIA2 in the second area A2.

A portion of the preliminary insulating layer PRE overlapping the light blocking portion LBA may not be removed by the developer. Accordingly, the upper surface of the second via-insulating layer VIA2 may include the convex portion defining the uneven structure CCS. The convex portion may overlap the scan bypass line SCL in a plan view. For example, the concave portion and the convex portion may be alternately arranged along one direction.

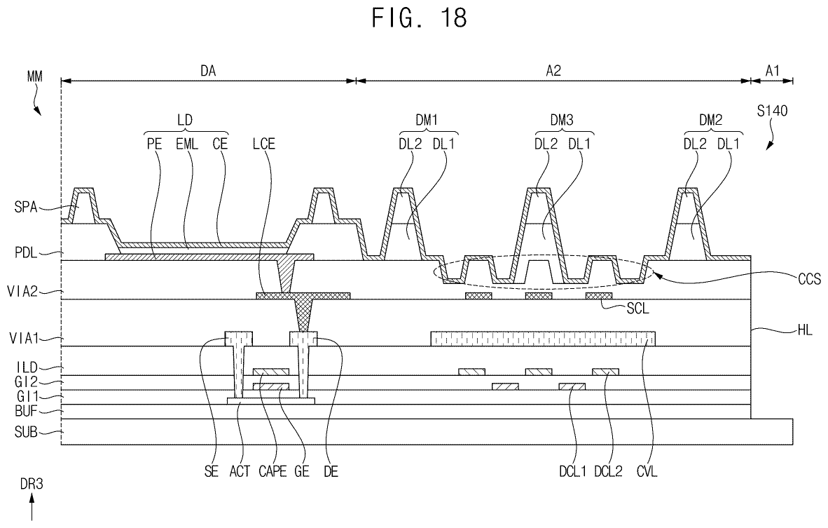

In FIGS. 16 and 17, the light blocking portion LBA is illustrated as overlapping all of the scan bypass lines SCL in a plan view, but the present disclosure is not necessarily limited thereto. In an embodiment, the scan bypass lines SCL may include the first scan bypass line (SCL1, see FIG. 8) and the second scan bypass line (SCL2, see FIG. 8), and the semi-transmitting portion STA may overlap the first scan bypass line SCL1 in a plan view, and the light blocking portion LBA may overlap the second scan bypass line SCL2 in a plan view. In this case, through a development process, the first scan bypass line SCL1 may overlap the concave portion of the uneven structure CCS in a plan view, and the second scan bypass line SCL2 may overlap the convex portion of the uneven structure CCS. In a subsequent process, the third dam portion (DM3, see FIG. 18) may be formed to overlap the first scan bypass line SCL1 in a plan view.

Referring to FIG. 18, the common electrode CE may be disposed along the profile of the uneven structure CCS on the second via-insulating layer VIA2 (S140).

The pixel electrode PE may be formed in the display area DA on the second via-insulating layer VIA2. The pixel electrode PE may be connected to the connection electrode LCE through a contact hole that penetrates the second via-insulating layer VIA2.

The pixel defining layer PDL may be formed on the second via-insulating layer VIA2. The pixel defining layer PDL may cover the edge of the pixel electrode PE, and may expose the upper surface of the pixel electrode PE. The spacer SPA may be disposed on the pixel defining layer PDL.

The first to third dam portions DM1, DM2, and DM3 may be formed in the second area A2 on the second via-insulating layer VIA2. The first to third dam portions DM1, DM2, and DM3 may be spaced apart from each other. For example, the first dam portion DM1 may be disposed in the second area A2 adjacent to the display area DA, the second dam portion DM2 may be disposed in the second area A2 adjacent to the first area A1 in which the through hole HL is defined, and the third dam portion DM3 may be disposed between the first dam portion DM1 and the second dam portion DM2. The third dam portion DM3 may overlap the uneven structure CCS of the second via-insulating layer VIA2.

In an embodiment, each of the first to third dam portions DM1, DM2, and DM3 may include the first dam layer DL1 and the second dam layer DL2 disposed on the first dam layer DL1. The first dam layer DL1 and the pixel defining layer PDL may include the same material and may be formed through the same process. The second dam layer DL2 and the spacer SPA may include the same material and may be formed through the same process.

In an embodiment, as illustrated in FIG. 18, the third dam portion DM3 may overlap the convex portion of the uneven structure CCS of the second via-insulating layer VIA2. In addition, the third dam portion DM3 may overlap the scan bypass line SCL in a plan view. However, the present disclosure is not necessarily limited thereto. In an embodiment, as illustrated in FIG. 9, the third dam portion DM3′ may overlap the concave portion of the uneven structure CCS of the second via-insulating layer VIA2.

The light-emitting layer EML may be formed in the display area DA on the pixel electrode PE. The common electrode CE may be formed on the second via-insulating layer VIA2. The common electrode CE may continuously extend over the display area DA and the second area A2. The common electrode CE may be disposed along the profiles of the first to third dam portions DM1, DM2, and DM3 and the second via-insulating layer VIA2 in the second area A2. That is, in an embodiment, the common electrode CE may be disposed along the profiles of the uneven structure CCS of the second via-insulating layer VIA2 and the third dam portion DM3 in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE.

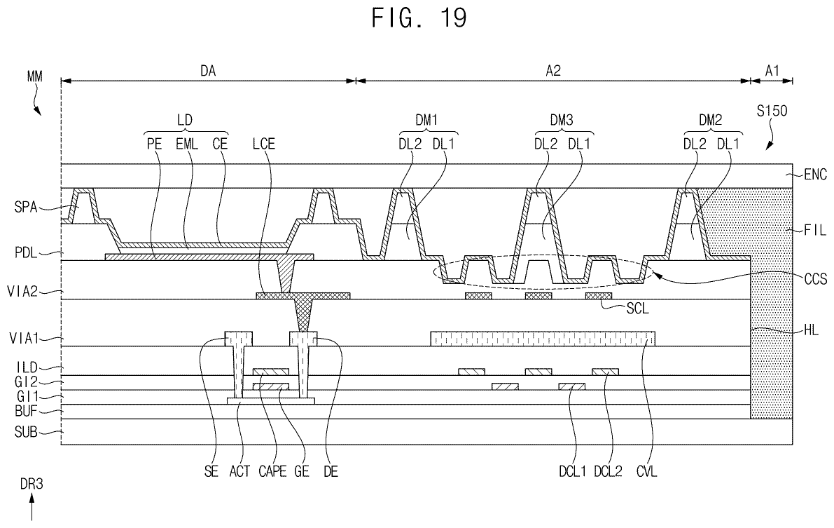

Referring to FIG. 19, the filling layer FIL filling inside the through hole HL may be formed (S150). The filling layer FIL may be disposed on the substrate SUB in the first area A1. In addition, the filling layer FIL may partially overlap the second area A2. In the process of filling the filling layer FIL inside the through hole HL, the first to third dam portions DM1, DM2, and DM3 may prevent the filling layer FIL from overflowing into the display area DA. In addition, even if the filling layer FIL overflows the second dam portion DM2, the concave portion of the second via-insulating layer VIA2 may accommodate the fluid overflowing the second dam portion DM2.

The encapsulation substrate ENC may be formed on the common electrode CE and the filling layer FIL (S150). The encapsulation substrate ENC may be entirely disposed over the first area A1, the second area A2, and the display area DA.

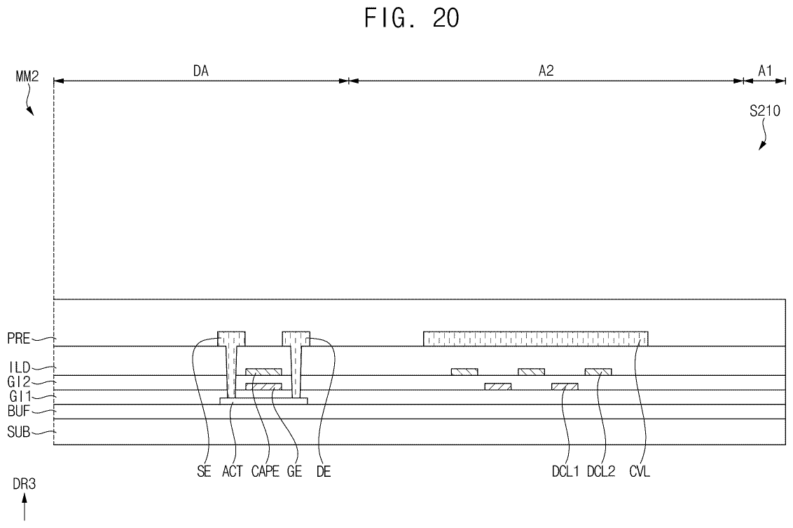

FIGS. 20, 21, 22, 23, and 24 are cross-sectional views illustrating a method of manufacturing a display device according to an embodiment of the present disclosure. A method MM2 of manufacturing a display device described with reference to FIGS. 20 to 24 may be a method of manufacturing the display device DD2 described above with reference to FIG. 11. Hereinafter, redundant descriptions of the display device DD2 described above with reference to FIG. 11 are omitted or summarized.

Referring to FIG. 20, the thin film transistor (TR, see FIG. 4) may be formed in the display area DA on the substrate SUB, and the first data bypass line DCL1, the second data bypass line DCL2, and the constant voltage line CVL may be formed in the second area A2 on the substrate SUB (S210). Hereinafter, redundant descriptions of the method MM of manufacturing the display device described above with reference to FIG. 14 are omitted or summarized.

The constant voltage line CVL may be formed in the second area A2 on the second data bypass line DCL2. For example, the constant voltage line CVL may be formed in the second area A2 on the inter-layer insulating layer ILD.

A preliminary insulating layer PRE may be formed on the second data bypass line DCL2 (S210). For example, the preliminary insulating layer PRE may be formed on the inter-layer insulating layer ILD. The preliminary insulating layer PRE may cover the source electrode SE, the drain electrode DE, and the constant voltage line CVL.

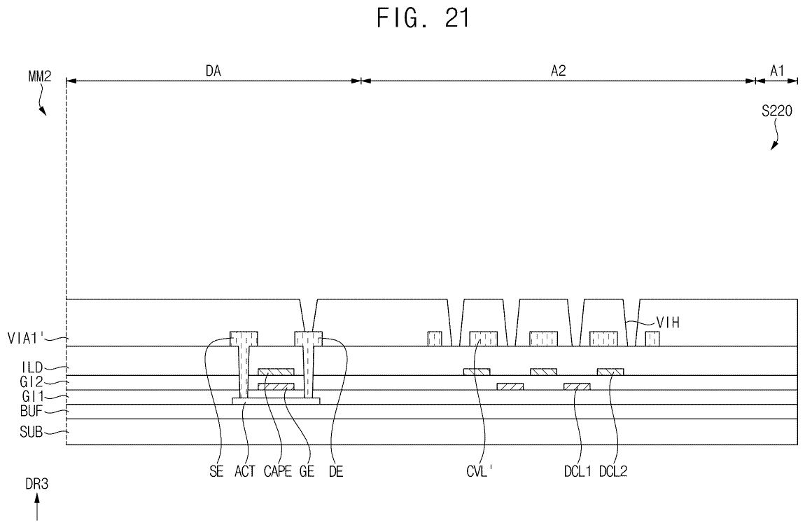

Referring to FIG. 21, the first via-insulating layer VIA1′ in which the via-holes VIH are defined and the constant voltage patterns CVL′ spaced apart from each other may be formed by patterning the preliminary insulating layer PRE and the constant voltage line CVL, respectively (S220).

In the second area A2, the via-holes VIH penetrating the first via-insulating layer VIA1′ may be formed in the first via-insulating layer VIA1′. The via-holes VIH may be spaced apart from each other. In the process of forming the via-holes VIH, the constant voltage line CVL may be patterned into the plurality of constant voltage patterns CVL′. That is, the constant voltage patterns CVL′ may be spaced apart from each other, and the via-holes VIH may be positioned between the constant voltage patterns CVL′. The first via-insulating layer VIA1′ may cover the constant voltage patterns CVL′.

In addition, in the process of forming the via-holes VIH, a contact hole exposing a portion of the drain electrode DE may be formed in the display area DA. The contact hole may penetrate the first via-insulating layer VIA1′.

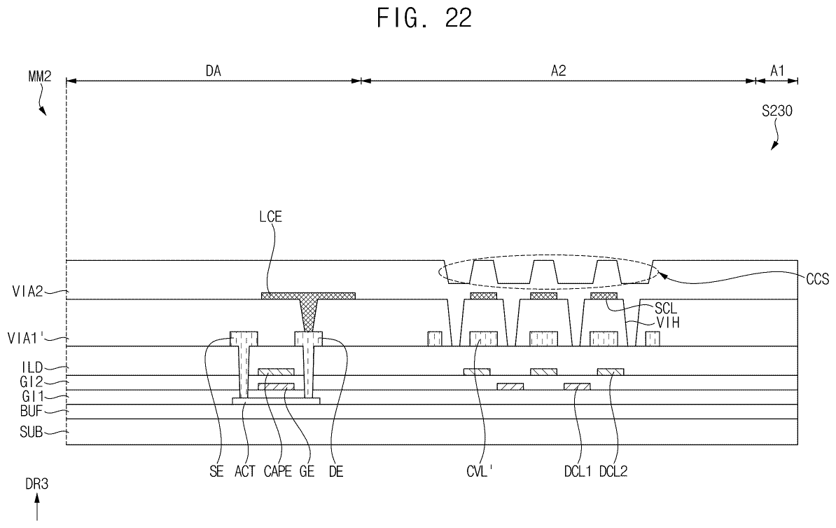

Referring to FIG. 22, the scan bypass line SCL may be formed on the first via-insulating layer VIA1′ (S230). The scan bypass line SCL may be disposed between the via-holes VIH in the second area A2. In an embodiment, the scan bypass line SCL may overlap the constant voltage pattern CVL′ in a plan view.

The connection electrode LCE may be formed in the display area DA on the first via-insulating layer VIA1′. The connection electrode LCE may be connected to the drain electrode DE through a contact hole that penetrates the first via-insulating layer VIA1′.

In an embodiment, the connection electrode LCE and the scan bypass line SCL may include the same material and may be formed through the same process.

The second via-insulating layer VIA2 may be formed on the first via-insulating layer VIA1′ (S230). The second via-insulating layer VIA2 may cover the scan bypass line SCL in the second area A2. In an embodiment, the second via-insulating layer VIA2 may be disposed along the profile of the first via-insulating layer VIA1′. That is, as the via-holes VIH are defined in the first via-insulating layer VIA1′, the upper surface of the second via-insulating layer VIA2 disposed along the profile of the first via-insulating layer VIA′ may have the uneven structure CCS. In this case, the upper surface of the second via-insulating layer VIA2 may include the concave portion and the convex portion defining the uneven structure CCS. In an embodiment, the concave portion may overlap the via-hole VIH in a plan view, and the convex portion may overlap the scan bypass line SCL in a plan view. For example, the concave portion and the convex portion may be alternately arranged along one direction.

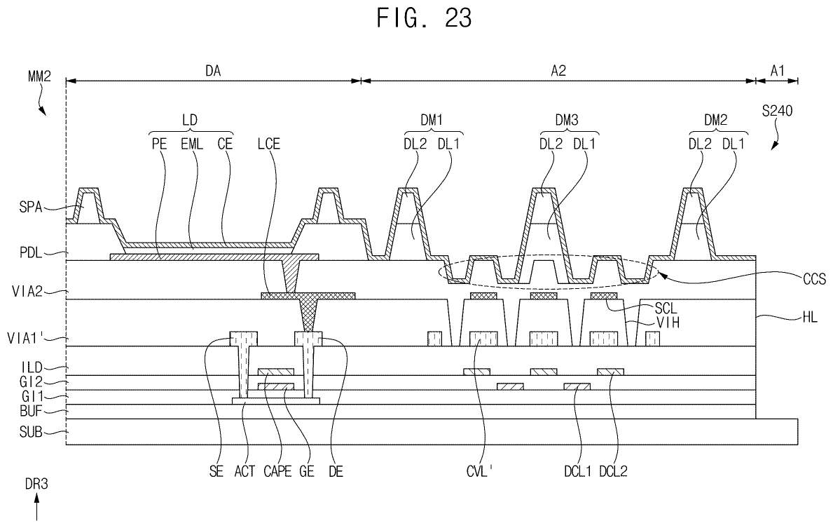

Referring to FIG. 23, the through hole HL may be formed in the first area A1 (S240). For example, a photomask may be positioned on the second via-insulating layer VIA2, and the photomask may include a light blocking portion and a transmitting portion. The light blocking portion may overlap the uneven structure CCS in a plan view, and the transmitting portion may overlap the first area A1. Through a developing process, the through hole HL that penetrates the buffer layer BUF, the first gate insulating layer GI1, the second gate insulating layer GI2, the inter-layer insulating layer ILD, the first via-insulating layer VIA1′, and the second via-insulating layer VIA2 may be formed in the first area A1, and the uneven structure CCS of the second via-insulating layer VIA2 may not be removed by a developer.

The pixel electrode PE may be formed in the display area DA on the second via-insulating layer VIA2. The pixel electrode PE may be connected to the connection electrode LCE.

The pixel defining layer PDL may be formed on the second via-insulating layer VIA2. The pixel defining layer PDL may cover the edge of the pixel electrode PE, and may expose the upper surface of the pixel electrode PE. The spacer SPA may be disposed on the pixel defining layer PDL.

The first to third dam portions DM1, DM2, and DM3 may be formed in the second area A2 on the second via-insulating layer VIA2. The first to third dam portions DM1, DM2, and DM3 may be spaced apart from each other. For example, the first dam portion DM1 may be disposed in the second area A2 adjacent to the display area DA, the second dam portion DM2 may be disposed in the second area A2 adjacent to the first area A1 in which the through hole HL is defined, and the third dam portion DM3 may be disposed between the first dam portion DM1 and the second dam portion DM2. The third dam portion DM3 may overlap the uneven structure CCS of the second via-insulating layer VIA2.

In an embodiment, each of the first to third dam portions DM1, DM2, and DM3 may include the first dam layer DL1 and the second dam layer DL2 disposed on the first dam layer DL1. The first dam layer DL1 and the pixel defining layer PDL may include the same material and may be formed through the same process. The second dam layer DL2 and the spacer SPA may include the same material and may be formed through the same process.

In an embodiment, as illustrated in FIG. 23, the third dam portion DM3 may overlap the convex portion of the uneven structure CCS of the second via-insulating layer VIA2. In addition, the third dam portion DM3 may overlap the scan bypass line SCL in a plan view. However, the present disclosure is not necessarily limited thereto. In an embodiment, as illustrated in FIG. 13, the third dam portion DM3′ may overlap the concave portion of the uneven structure CCS of the second via-insulating layer VIA2.

The light-emitting layer EML may be formed in the display area DA on the pixel electrode PE. The common electrode CE may be formed on the second via-insulating layer VIA2 (S240). The common electrode CE may continuously extend along the display area DA and the second area A2. The common electrode CE may be disposed along the profiles of the first to third dam portions DM1, DM2, and DM3 and the second via-insulating layer VIA2 in the second area A2. That is, in an embodiment, the common electrode CE may be disposed along the profiles of the uneven structure CCS of the second via-insulating layer VIA2 and the third dam portion DM3 in the second area A2.

The convex portion defining the uneven structure CCS of the second via-insulating layer VIA2 may overlap the scan bypass line SCL in a plan view. As the common electrode CE is disposed along the profile of the convex portion of the uneven structure CCS, the convex portion may increase a separation distance between the scan bypass line SCL and the common electrode CE.

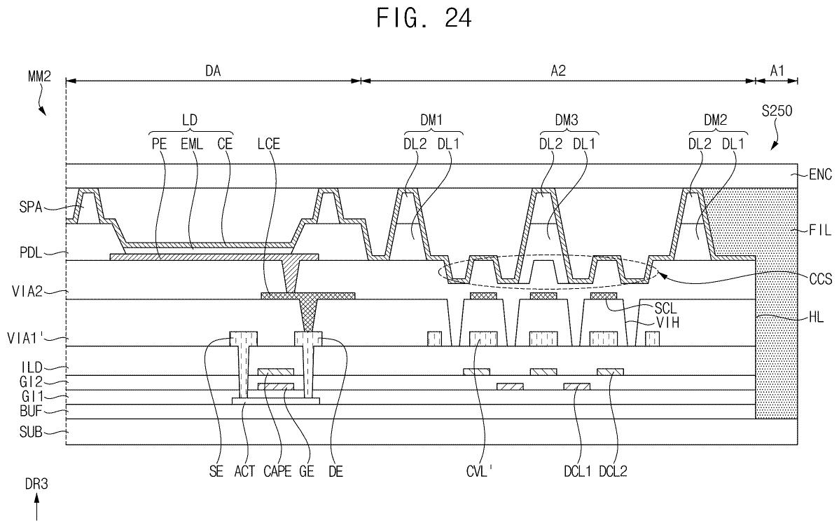

Referring to FIG. 24, the filling layer FIL filling the inside of the through hole HL may be formed, and the encapsulation substrate ENC may be formed on the common electrode CE and the filling layer FIL (S250). Hereinafter, redundant descriptions of the method MM of manufacturing the display device described above with reference to FIG. 19 are omitted.

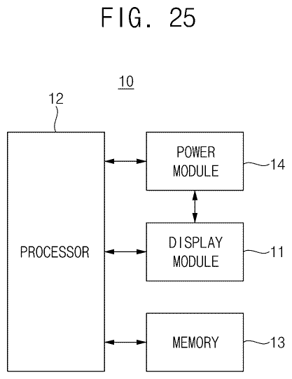

FIG. 25 is a block diagram of an electronic device according to an embodiment of the present disclosure.

Referring to FIG. 25, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

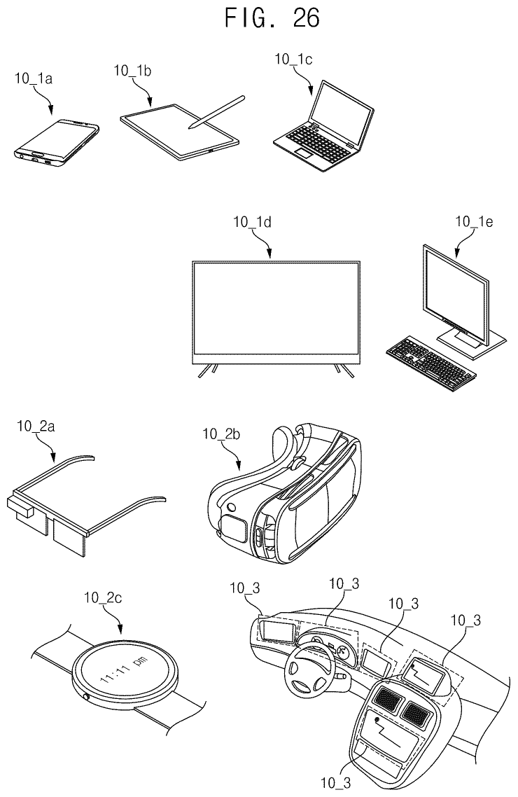

FIG. 26 is a schematic view of an electronic device according to various embodiments.

Referring to FIG. 26, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate comprising a first area, a second area surrounding the first area in plan view, and a display area surrounding the second area in the plan view;
pixels on the display area of the substrate;
a data bypass line on the second area of the substrate;
a first insulating layer on the data bypass line;
a scan bypass line on the first insulating layer on the second area of the substrate;
a second insulating layer on the first insulating layer, the second insulating layer covering the scan bypass line, the second insulating layer including a concave portion and a convex portion which define an uneven structure, wherein the convex portion overlaps the scan bypass line in the plan view; and
a common electrode on the second insulating layer and disposed along a profile of the uneven structure, wherein
the first insulating layer and the second insulating layer define part of a through hole over the first area of the substrate,
the data bypass line extends to bend along a border of the through hole in the plan view, and
the scan bypass line extends to bend along the border of the through hole in the plan view.

2. The display device of claim 1, further comprising:
a dam portion on the second insulating layer and overlapping the uneven structure,
wherein the common electrode is disposed along the profile of the uneven structure and a profile of the dam portion.

3. The display device of claim 2, wherein the dam portion overlaps the convex portion of the uneven structure.

4. The display device of claim 2, wherein the dam portion overlaps the concave portion of the uneven structure.

5. The display device of claim 4, wherein the dam portion is spaced apart from the scan bypass line in the plan view.

6. The display device of claim 4,
wherein the scan bypass line includes a plurality of scan bypass lines,
wherein the plurality of scan bypass lines comprise a first scan bypass line and a second scan bypass line, and
wherein the first scan bypass line overlaps the dam portion in the plan view, and
the second scan bypass line overlaps the convex portion of the uneven structure in the plan view.

7. The display device of claim 1, further comprising:
a gate electrode on the display area of the substrate;
a capacitor electrode on the gate electrode;
a source electrode and a drain electrode on the capacitor electrode; and
a connection electrode on the drain electrode,
wherein the data bypass line includes a plurality of data bypass lines,
wherein the plurality of data bypass lines comprise a first data bypass line and a second data bypass line, and
wherein the first data bypass line and the second data bypass line are in different layers.

8. The display device of claim 7,
wherein the first data bypass line is in a same layer as the gate electrode,
wherein the second data bypass line is in a same layer as the capacitor electrode, and
wherein the scan bypass line is in a same layer as the connection electrode.

9. The display device of claim 1, further comprising:
a first driver in a peripheral area of the substrate; and
a second driver in the peripheral area of the substrate, wherein
the peripheral area of the substrate further surrounds at least a portion of the display area,
the first driver is adjacent to a first side of the display area,
the second driver is adjacent to a second side of the display area,
the second side of the display area is opposite the first side of the display area,
the first driver is configured to output a scan signal to the scan bypass line while the scan signal is not output by the second driver.

10. The display device of claim 1, further comprising:
a constant voltage line between the data bypass line and the scan bypass line, wherein the constant voltage line is configured to have a constant voltage applied thereto,
the scan bypass line overlaps the constant voltage line in the plan view.

11. The display device of claim 1, further comprising:
a plurality of constant voltage patterns spaced apart from each other between the data bypass line and the scan bypass line, the plurality of constant voltage patterns being configured to have a constant voltage applied thereto,
wherein the scan bypass line includes a plurality of scan bypass lines, and
wherein the plurality of scan bypass lines overlap the plurality of constant voltage patterns in the plan view, respectively.

12. The display device of claim 11, wherein the first insulating layer defines a plurality of via-holes between the plurality of constant voltage patterns.

13. The display device of claim 12, wherein the second insulating layer is disposed along a profile of the first insulating layer.

14. The display device of claim 12, wherein the plurality of scan bypass lines are between the plurality of via-holes in the plan view.

15. A method of manufacturing a display device, the method comprising:
forming a data bypass line on a second area of a substrate,
the substrate comprising a first area, the second area surrounding the first area in a plan view, and a display area surrounding the second area in the plan view;
forming a first insulating layer on the data bypass line;
forming a scan bypass line on the first insulating layer over the second area of the substrate;
forming a second insulating layer on the first insulating layer and covering the scan bypass line, the second insulating layer including a concave portion and a convex portion which define an uneven structure on the first insulating layer; and
forming a common electrode disposed along a profile of the uneven structure on the second insulating layer,
wherein the convex portion overlaps the scan bypass line in the plan view.

16. The method of claim 15, wherein the forming the second insulating layer comprises:
forming a preliminary insulating layer covering the scan bypass line on the first insulating layer; and
patterning the preliminary insulating layer using a photomask comprising a semi-transmitting portion.

17. The method of claim 16,
wherein the forming the scan bypass line includes forming a plurality of scan bypass lines on the first insulating layer over the second area of the substrate, and
wherein the photomask comprises a light-blocking portion which overlaps the plurality of scan bypass lines in the plan view and the semi-transmitting portion which overlaps spaced areas between the plurality of scan bypass lines in the plan view.

18. The method of claim 15, further comprising:
forming a constant voltage line over the data bypass line before forming the scan bypass line, wherein
the constant voltage line is between the data bypass line and the scan bypass line, and
the constant voltage line is configured to have a constant voltage applied thereto.

19. The method of claim 18,
wherein the forming the first insulating layer comprises
forming a preliminary insulating layer covering the constant voltage line on the data bypass line, and
forming the first insulating layer in which a plurality of via-holes are defined and a plurality of constant voltage patterns spaced apart from each other by patterning the preliminary insulating layer and the constant voltage line, respectively, and
wherein the second insulating layer is disposed along a profile of the first insulating layer.

20. An electronic device comprising:
a display device; and
a processor configured to transmit an image data signal and an input control signal to the display device, wherein
the display device comprises
a substrate comprising a first area, a second area surrounding the first area in a plan view, and a display area surrounding the second area in the plan view,
pixels on the display area of the substrate,
a functional module under the substrate and overlapping the first area,
a data bypass line on the second area of the substrate,
a first insulating layer on the data bypass line,
a scan bypass line on the first insulating layer on the second area of the substrate,
a second insulating layer on the first insulating layer, the second insulating layer covering the scan bypass line, and the second insulating layer including a concave portion and a convex portion which define an uneven structure, wherein the convex portion overlaps the scan bypass line in the plan view, and
a common electrode on the second insulating layer and along a profile of the uneven structure,
wherein the first insulating layer and the second insulating layer define part of a through hole over the first area of the substrate, the data bypass line extends to bend along a border of the through hole in the plan view, and the scan bypass line extends to bend along the border of the through hole in the plan view.
